(19) United States
(12) Patent Application Publication
(10) Pub. No.: US 2024/0045318 A1
(43) Pub. Date: Feb. 8, 2024

(54) EXTREME ULTRAVIOLET MASK WITH DIFFUSION BARRIER LAYER

(71) Applicant: TAIWAN SEMICONDUCTOR MANUFACTURING COMPANY, LTD., Hsinchu (TW)

(72) Inventors: Hsin-Chang LEE, Hsinchu County (TW); Pei-Cheng HSU, Taipei City (TW); Wei-Hao LEE, Taipei City (TW); Bo-Wei SHIH, Changhua County (TW); Ta-Cheng LIEN, Hsinchu County (TW)

(73) Assignee: TAIWAN SEMICONDUCTOR MANUFACTURING COMPANY, LTD., Hsinchu (TW)

(21) Appl. No.: 17/880,019

(22) Filed: Aug. 3, 2022

(51) Int. Cl. G03F 1/24; G03F 1/54; G03F 1/80; C23C 14/22

(52) U.S. Cl. CPC G03F 1/24; G03F 1/54; G03F 1/80; C23C 14/221

(57) ABSTRACT

An extreme ultraviolet (EUV) mask includes a substrate, a reflective multilayer stack on the substrate, a diffusion barrier layer, a capping layer and a patterned absorber layer. The reflective multilayer stack comprises alternately stacked first layers and second layers. The diffusion barrier layer is on the reflective multilayer stack. The diffusion barrier layer has a composition different from compositions of the first layers and the second layers. The capping layer is on the diffusion barrier layer. The patterned absorber layer is on the reflective multilayer stack.

### BACKGROUND

The semiconductor industry has experienced exponential growth. Technological advances in materials and design have produced generations of integrated circuits (ICs), where each generation has smaller and more complex circuits than the previous generation. In the course of IC evolution, functional density (i.e., the number of interconnected devices per chip area) has generally increased while geometry size (i.e., the smallest component or line that can be created using a fabrication process) has decreased. This scaling down process generally provides benefits by increasing production efficiency and lowering associated costs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic view of an extreme ultraviolet (EUV) lithography tool with an LPP-based EUV radiation source, in accordance with some embodiments of the present disclosure.

FIG. 1B is a simplified schematic diagram of a detail of an extreme ultraviolet lithography tool according to an embodiment of the disclosure showing the exposure of photoresist coated substrate with a patterned beam of EUV light.

FIGS. 2A and 2B are cross-sectional views of EUV blank masks constructed in accordance with some embodiments of the present disclosure.

FIG. 3 is a schematic top-view diagram of an exemplary multi-chamber processing system in accordance with some embodiments.

FIGS. 4-23 show cross-sectional views of fabrication of the EUV blank mask at various stages in accordance with some embodiments.

FIGS. 24A and 24B are cross-sectional views of various stages of a process for forming an EUV mask in accordance with some embodiments.

FIG. 25 shows a flowchart illustrating a method of extreme ultraviolet lithography (EUVL) according to an embodiment of the present disclosure.

FIGS. 26A and 26B show a photo mask data generating apparatus according to an embodiment of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise specified, the same or similar reference numerals in different figures refer to the same or similar component formed by a same or similar process using a same or similar material(s).

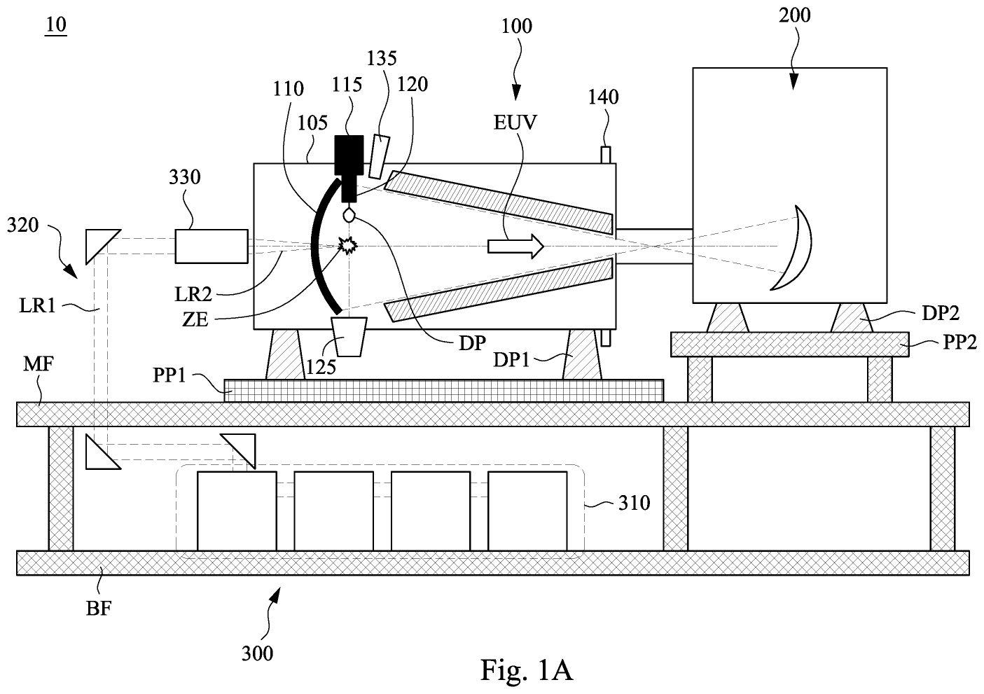

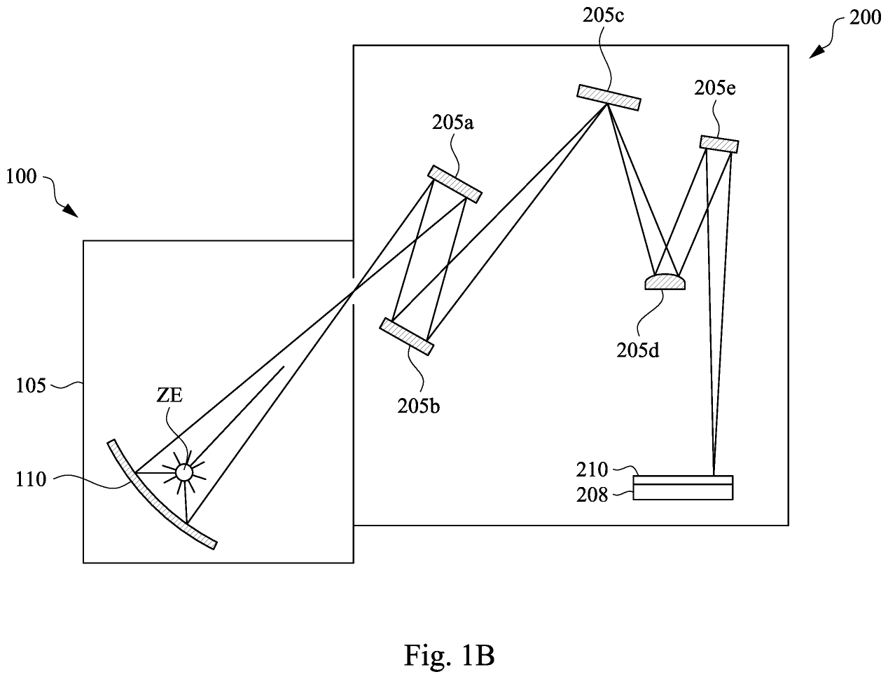

FIG. 1A is a schematic view diagram of an EUV lithography system 10, constructed in accordance with some embodiments. The EUV lithography system 10 may also be generically referred to as a scanner that is configured to perform Lithography exposure processes with respective radiation source and exposure mode. The EUV lithography system 10 is designed to expose a photoresist layer by EUV light or EUV radiation. The photoresist layer is a material sensitive to the BUY light. The EUV lithography system 10 employs a radiation source 100 to generate EUV light, such as BUY light having a wavelength ranging between about 1 nm and about 100 nm. In one particular example, the radiation source 100 generates a EUV light with a wavelength centered at about 13.5 am. Accordingly, the radiation source 100 is also referred to as BUY radiation source 100.

Extreme ultraviolet (EUV) lithography has become widely used due to its ability to achieve small semiconductor device sizes, for example for 20 nanometer (nm) technology nodes. Because most materials are highly absorbing at the wavelength of 13.5 am, EUV lithography utilizes a reflective-type EUV mask having a reflective multilayer to reflect the incident EUV light and an absorber layer on top of the reflective multilayer to absorb radiation in areas where light is not supposed to be reflected by the mask. The mask pattern is defined by the absorber layer and is transferred to a semiconductor wafer by reflecting BUY light off portions of a reflective surface of the EUV mask.

A capping layer may be disposed over a topmost surface of the reflective multilayer to help protect the reflective multilayer from oxidation and any chemical etchants to which the reflective multilayer may be exposed during subsequent mask fabrication processes.

The capping layer may suffer from poor durability caused by its polycrystalline structure including multiple grain boundaries or being weakened by etching or clean processes such that oxygen can pass through the capping layer and easily oxidize a top of the reflective multilayer to form an oxide layer. Another reason for causing the poor durability of the capping layer is that interdiffusion may be unintentionally formed between the reflective multilayer and the capping layer due to a post-deposition annealing configured to reduce stress of the EUV blank mask. The interdiffusion may result in thickness reduction in the capping layer, disadvantageously affecting its durability under a subsequent etching process.

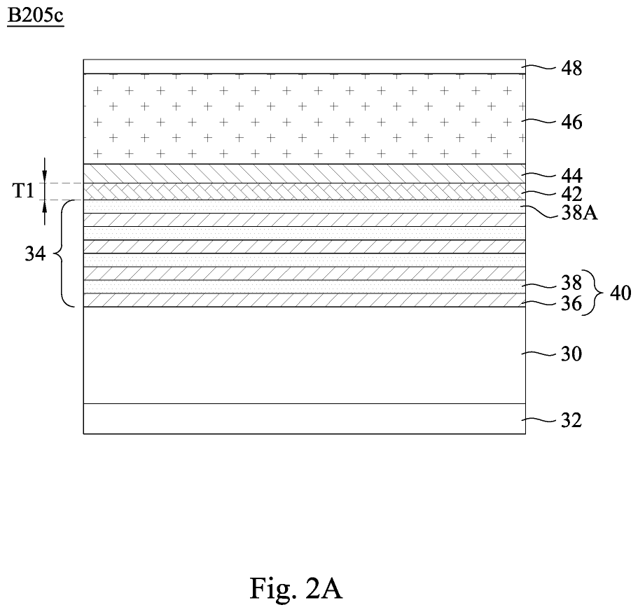

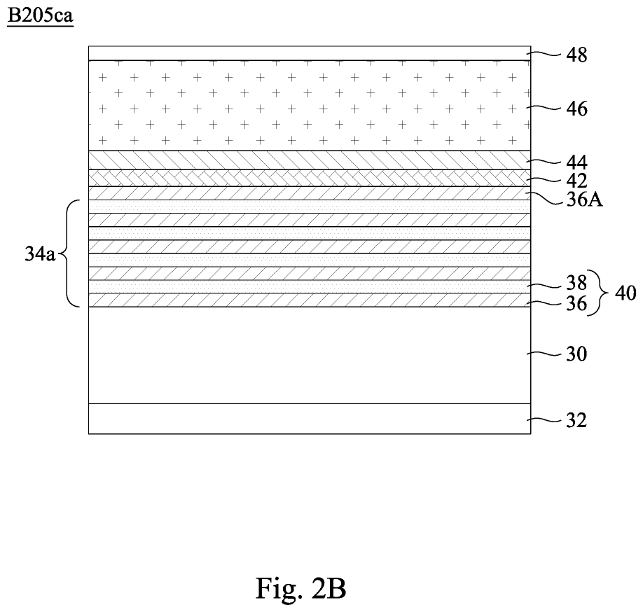

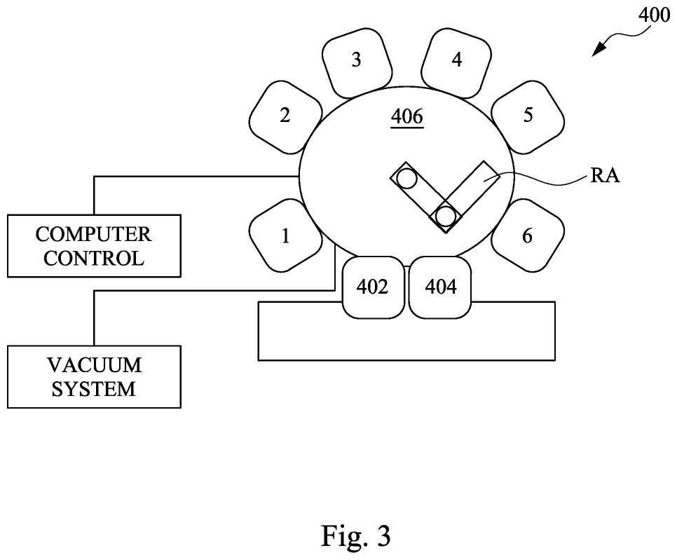

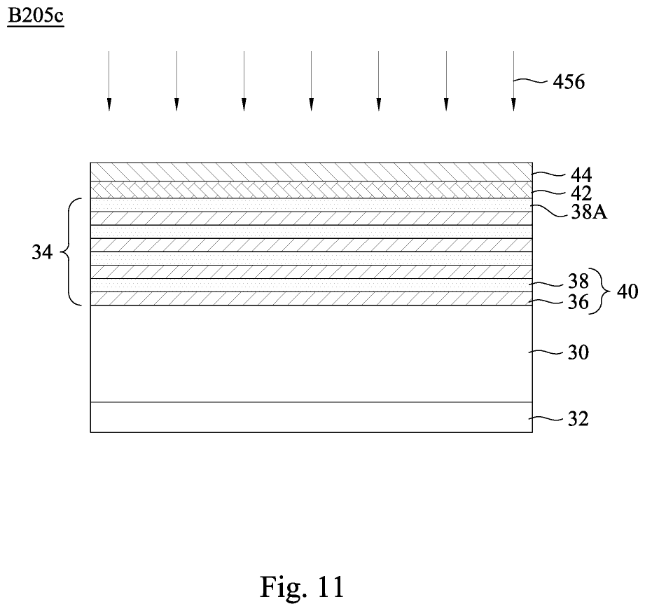

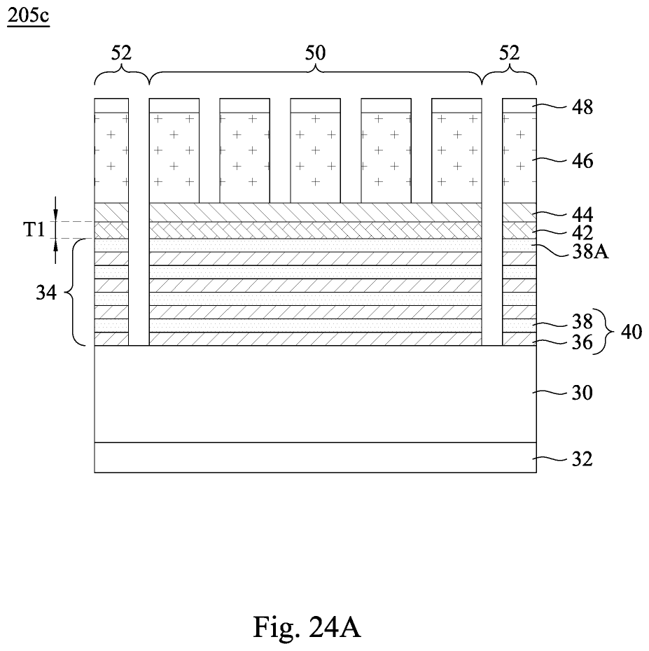

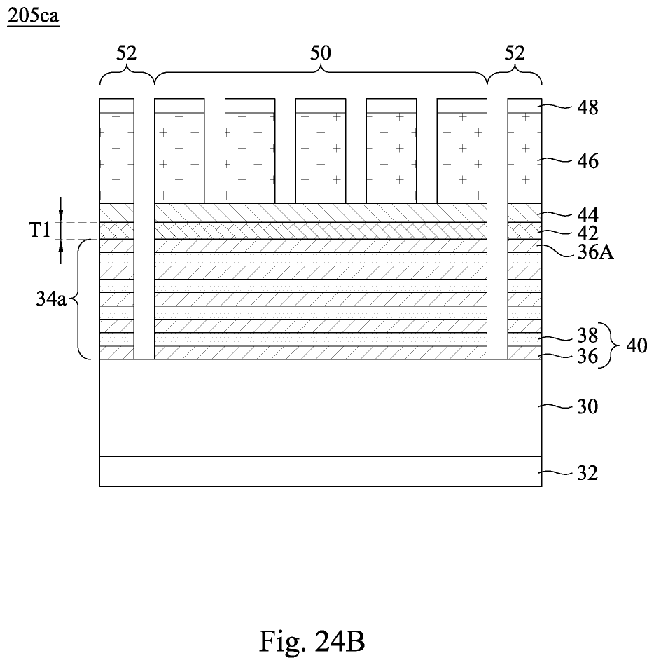

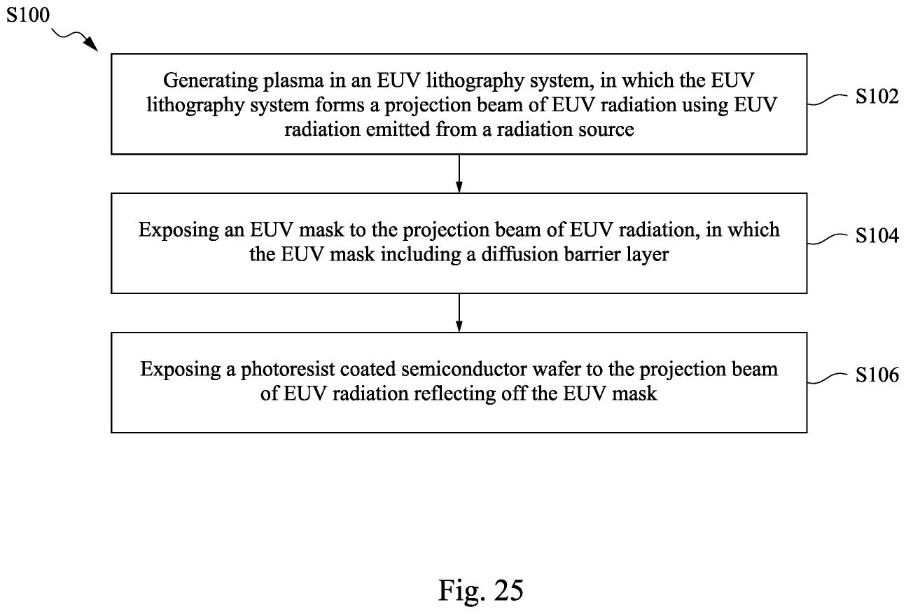

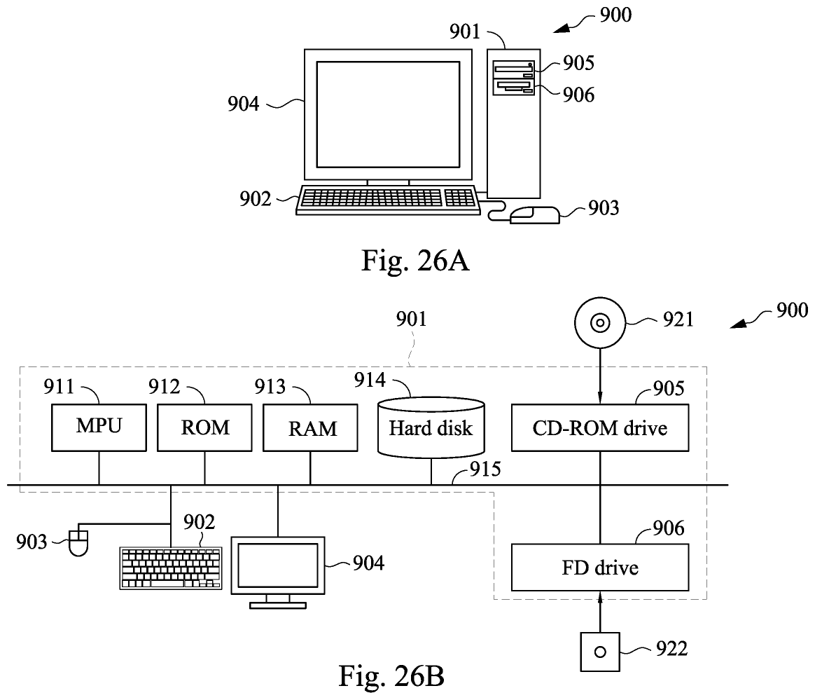

The present disclosure provides a novel diffusion barrier layer disposed between the reflective multilayer and the capping layer. Therefore, interdiffusion between the reflective multilayer and the capping layer can be prevented, ensuring the desired durability of the capping layer. The various aspects of the present disclosure will be discussed below in greater detail with reference to FIGS. 1A-26B. First, a EUV lithography system will be discussed below with reference to FIGS. 1A and 1B. The details of the EUV blank mask will be discussed with reference to FIGS. 2A and 2B. The details of the fabrication of the EUV blank mask will be discussed with reference to FIGS. 3-23. The details of the fabrication of the EUV mask will be discussed with reference to FIGS. 24A and 24B. The details of a method of extreme ultraviolet lithography (EUVL) will be discussed with reference to FIGS. 25, 26A and 26B.

The advanced lithography process, method, and materials described in the current disclosure can be used in many applications, including fin-type field effect transistors (FinFETs), gate-all-around (GAA) FETs. For example, the fins may be patterned to produce a relatively close spacing between features, for which the above disclosure is well suited. In addition, spacers used in forming fins of FinFETs can be processed according to the above disclosure.

To address the trend of the Moore's law for decreasing size of chip components and the demand of higher computing power chips for mobile electronic devices such as smart phones with computer functions, multi-tasking capabilities, or even with workstation power. Smaller wavelength photolithography exposure systems are desirable. Extreme ultraviolet (EUV) photolithography technique uses an EUV radiation source to emit an EUV light ray with wavelength of about 13.5 nm. Because this wavelength is also in the x-ray radiation wavelength region, the EUV radiation source is also called a soft x-ray radiation source. The EUV light rays emitted from a laser-produced plasma (LFP) are collected by a collector mirror and reflected toward a patterned mask.

FIG. 1A is a schematic view of an EUV lithography tool with an LFP-based EUV radiation source, in accordance with some embodiments of the present disclosure. The EUV lithography system includes an EUV radiation source 100 to generate EUV radiation, an exposure device 200, such as a scanner, and an excitation laser source 300. As shown in FIG. 1A, in some embodiments, the EUV radiation source 100 and the exposure device 200 are installed on a main floor MF of a clean room, while the excitation laser source 300 is installed in a base floor BF located under the main floor MF. Each of the EUV radiation source 100 and the exposure device 200 are placed over pedestal plates PP1 and PP2 via dampers DP1 and DP2, respectively. The EUV radiation source 100 and the exposure device 200 are coupled to each other by a coupling mechanism, which may include a focusing unit.

The EUV lithography tool is designed to expose a resist layer to EUV light (also interchangeably referred to herein as EUV radiation). The resist layer is a material sensitive to the EUV light. The EUV lithography system employs the BUY radiation source 100 to generate BUY light, such as EUV light having a wavelength ranging between about 1 nm and about 100 nm. In one particular example, the EUV radiation source 100 generates an EUV light with a wavelength centered at about 13.5 nm. In the present embodiment, the EUV radiation source 100 utilizes a mechanism of laser-produced plasma (LPP) to generate the EUV radiation.

The exposure device 200 includes various reflective optic components, such as convex/concave/flat mirrors, a mask holding mechanism including a mask stage, and wafer holding mechanism. The EUV radiation EUV generated by the EUV radiation source 100 is guided by the reflective optical components onto a mask secured on the mask stage. In some embodiments, the mask stage includes an electrostatic chuck (e-chuck) to secure the mask.

FIG. 1B is a simplified schematic diagram of a detail of an extreme ultraviolet lithography tool according to an embodiment of the disclosure showing the exposure of photoresist coated substrate 210 secured on a substrate stage 208 of the exposure device 200 with a patterned beam of EUV light. The exposure device 200 is an integrated circuit lithography tool such as a stepper, scanner, step and scan system, direct write system, device using a contact and/or proximity mask, etc., provided with one or more optics 205a, 205b, for example, to illuminate a patterning optic 205c, such as a reticle, with a beam of EUV light, to produce a patterned beam, and one or more reduction projection optics 205d, 205e, for projecting the patterned beam onto the photoresist coated substrate 210. A mechanical assembly (not shown) may be provided for generating a controlled relative movement between the photoresist coated substrate 210 and the patterning optic 205c. As further shown in FIG. 1A, the EUVL tool includes an EUV radiation source 100 including an EUV light radiator ZE emitting EUV light in a chamber 105 that is reflected by a collector 110 along a path into the exposure device 200 to irradiate the photoresist coated substrate 210.

As used herein, the term “optic” is meant to be broadly construed to include, and not necessarily be limited to, one or more components which reflect and/or transmit and/or operate on incident light, and includes, but is not limited to, one or more lenses, windows, filters, wedges, prisms, grisms, gradings, transmission fibers, etalons, diffusers, homogenizers, detectors and other instrument components, apertures, axicons and mirrors including multi-layer mirrors, near-normal incidence mirrors, grazing incidence mirrors, specular reflectors, diffuse reflectors and combinations thereof. Moreover, unless otherwise specified, the term “optic”, as used herein, is directed to, but not limited to, components which operate solely or to advantage within one or more specific wavelength range(s) such as at the EUV output light wavelength, the irradiation laser wavelength, a wavelength suitable for metrology or any other specific wavelength.

In various embodiments of the present disclosure, the photoresist coated substrate 210 is a semiconductor wafer, such as a silicon wafer or other type of wafer to be patterned. The EUVL tool further includes other modules or is integrated with (or coupled with) other modules in some embodiments.

As shown in FIG. 1A, the EUV radiation source 100 includes a target droplet generator 115 and a collector 110, enclosed by a chamber 105. For example, the collector 110 is a laser-produced plasma (LPP) collector. In various embodiments, the target droplet generator 115 includes a reservoir to hold a source material and a nozzle 120 through which target droplets DP of the source material are supplied into the chamber 105.

In some embodiments, the target droplets DP are metal droplets of tin (Sn), lithium (Li), or an alloy of Sn and Li. In some embodiments, the target droplets DP each have a diameter in a range from about 10 microns (μm) to about 100 μm. For example, in an embodiment, the target droplets DP are tin droplets, having a diameter of about 10 μm to about 100 sm. In other embodiments, the target droplets DP are tin droplets having a diameter of about 25 μm to about 50 μm. In some embodiments, the target droplets DP are supplied through the nozzle 120 at a rate in a range from about 50 droplets per second (i.e., an ejection-frequency of about 50 Hz) to about 50,000 droplets per second (i.e., an ejection-frequency of about 50 kHz).

Referring back to FIG. 1A, an excitation laser LR2 generated by the excitation laser source 300 is a pulse laser. The laser pulses LR2 are generated by the excitation laser source 300. The excitation laser source 300 may include a laser generator 310, laser guide optics 320 and a focusing apparatus 330. In some embodiments, the laser generator 310 includes a carbon dioxide (CO₂) or a neodymium-doped yttrium aluminum garnet (Nd:YAG) laser source with a wavelength in the infrared region of the electromagnetic spectrum. For example, the laser generator 310 has a wavelength of about 9.4 μm or about 10.6 μm, in an embodiment. The laser light LR1 generated by the laser generator 310 is guided by the laser guide optics 320 and focused into the excitation laser LR2 by the focusing apparatus 330, and then introduced into the EUV radiation source 100.

In some embodiments, the excitation laser LR2 includes a pre-heat laser and a main laser. In such embodiments, the pre-heat laser pulse (interchangeably referred to herein as the “pre-pulse”) is used to heat (or pre-heat) a given target droplet to create a low-density target plume with multiple smaller droplets, which is subsequently heated (or reheated) by a pulse from the main laser, generating increased emission of EUV light.

In various embodiments, the pre-heat laser pulses have a spot size about 100 μm or less, and the main laser pulses have a spot size in a range of about 150 μm to about 300 μm. In some embodiments, the pre-heat laser and the main laser pulses have a pulse-duration in the range from about 10 ns to about 50 ns, and a pulse-frequency in the range from about 1 kHz to about 100 kHz. In various embodiments, the pre-heat laser and the main laser have an average power in the range from about 1 kilowatt (kW) to about 50 kW. The pulse-frequency of the excitation laser LR2 is matched with (e.g., synchronized with) the ejection-frequency of the target droplets DP in an embodiment.

The excitation laser LR2 is directed through windows (or lenses) into the zone of excitation ZE in front of the collector 110. The windows are made of a suitable material substantially transparent to the laser beams. The generation of the pulse lasers is synchronized with the ejection of the target droplets DP through the nozzle 120. As the target droplets move through the excitation zone, the pre-pulses heat the target droplets and transform them into low-density target plumes. A delay between the pre-pulse and the main pulse is controlled to allow the target plume to form and to expand to an optimal size and geometry. In various embodiments, the pre-pulse and the main pulse have the same pulse-duration and peak power. When the main pulse heats the target plume, a high-temperature plasma is generated. The plasma emits EUV radiation EUV, which is collected by the collector 110. The collector 110 further reflects and focuses the EUV radiation for the lithography exposing processes performed through the exposure device 200. The droplet catcher 125 is used for catching excessive target droplets. For example, some target droplets may be purposely missed by the laser pulses.

In some embodiments, the collector 110 is designed with a proper coating material and shape to function as a mirror for EUV collection, reflection, and focusing. In some embodiments, the collector 110 is designed to have an ellipsoidal geometry. In some embodiments, the coating material of the collector 110 is similar to the reflective multilayer of the EUV mask. In some examples, the coating material of the collector 110 includes a multilayer (ML) structure, such as a plurality of Mo/Si film pairs, and may further include a capping layer (such as Ru) coated on the ML structure to substantially reflect the EUV light. In some embodiments, the collector 110 may further include a grating structure designed to effectively scatter the laser beam directed onto the collector 110. For example, a silicon nitride layer is coated on the collector 110 and is patterned to have a grating pattern.

In the present disclosure, the terms mask, photomask, and reticle are used interchangeably. In the present embodiment, the patterning optic 205c is a reflective mask 205c. The reflective mask 205c also includes a reflective ML structure deposited on the substrate. The ML structure includes a plurality of film pairs, such as molybdenum-silicon (Mo/Si) film pairs (e.g., a layer of molybdenum above or below a layer of silicon in each film pair). Alternatively, the ML structure may include molybdenum-beryllium (Mo/Be) film pairs, or other suitable materials that are configurable to highly reflect the EUV light.

The mask 205c may further include a capping layer, such as ruthenium (Ru), disposed on the ML structure for protection. The mask 205c further includes an absorption layer deposited over the ML structure. The absorption layer is patterned to define a layer of an integrated circuit (IC), the absorber layer is discussed below in greater detail according to various aspects of the present disclosure. Alternatively, another reflective layer may be deposited over the ML structure and is patterned to define a layer of an integrated circuit, thereby forming a EUV phase shift mask.

The mask 205c and the method making the same are further described in accordance with some embodiments. In some embodiments, the mask fabrication process includes two operations: a blank mask fabrication process and a mask patterning process. During the blank mask fabrication process, a blank mask is formed by deposing suitable layers (e.g., reflective multiple layers) on a suitable substrate. The blank mask is then patterned during the mask patterning process to achieve a desired design of a layer of an integrated circuit (IC). The patterned mask is then used to transfer circuit patterns (e.g., the design of a layer of an IC) onto a semiconductor wafer. The patterns can be transferred over and over onto multiple wafers through various lithography processes. A set of masks is used to construct a complete IC.

One example of a reflective blank mask B205c is shown in FIG. 2A. The reflective blank mask B205c in the illustrated embodiment is a EUV mask, and includes a substrate 30 made of a LTEM. The LTEM material may include TiO₂ doped SiO₂, and/or other low thermal expansion materials known in the art. In some embodiments, a conductive layer 32 is additionally disposed under on the backside of the substrate 30 for the electrostatic chucking purpose. In one example, the conductive layer 32 includes chromium nitride (CrN), TaB, though other suitable compositions are possible.

The reflective blank mask B205c includes a reflective multilayer (ML) structure 34 disposed over the substrate 30. The ML structure 34 may be selected such that it provides a high reflectivity to a selected radiation type/wavelength. The ML structure 34 includes a plurality of film pairs 40, such as Mo/Si film pairs. For example, a layer 36 of molybdenum below a layer 38 of silicon in each film pair 40. In this embodiment, the ML structure 34 includes a topmost layer 38A made of silicon. In some other embodiments, the ML structure 34 may include any materials with refractive index difference being highly reflective at EUV wavelengths. In some embodiments, the layer 36 has a thickness of 4±0.1 nm, and the layer 38 has a thickness of 3±0.1 nm.

Still referring to FIG. 2A, the reflective blank mask B205c includes a diffusion barrier layer 42 and a capping layer 44 disposed over the ML structure 34 in sequence. That is, the diffusion barrier layer 42 is disposed between the ML structure 34 and the capping layer 44. In other words, the diffusion barrier layer 42 interposes the ML structure 34 and the capping layer 44. In some embodiments, the capping layer 44 includes a material that resists oxidation and corrosion, and has a low chemical reactivity with common atmospheric gas species such as oxygen, nitrogen, and water vapor. In some embodiments, the capping layer 44 includes a transition metal such as, for example, ruthenium (Ru), iridium (Ir), rhodium (Rh), platinum (Pt), palladium (Pd), osmium (Os), rhenium (Re), vanadium (V), tantalum (Ta), hafnium (Hf), tungsten (W), molybdenum (Mo), zirconium (Zr), manganese (Mn), technetium (Tc), or alloys thereof. In some embodiments, the capping layer 44 includes RuNb having about 20 atomic % of Nb and has a thickness in a range from 2 nm to 4 nm.

The diffusion barrier layer 42 has a composition different from compositions of the layers 36 and 38 of the ML structure 34 and the capping layer 44. In some embodiments, the diffusion barrier layer 42 is free from molybdenum and Ru. In other words, the diffusion barrier layer 42 can be ruthenium-free. The diffusion barrier layer 42 has a lower reactivity with the capping layer 44 than the topmost layer 38A of the ML structure 34. Therefore, the diffusion barrier layer 42 is less likely to interdiffuse with the capping layer 44 as compared to the topmost layer 38A of the ML structure 34. For example, in a heat treatment (e.g., an anneal process), the diffusion barrier layer 42 does not interdiffuse with the capping layer. In some embodiments where the capping layer 44 is Ru, the diffusion barrier layer 42 is less likely to diffuse with the capping layer 44 as compared to the topmost layer 38A made of silicon. As a result, the interdiffusion between the ML structure 34 and the capping layer 44 can be prevented, thus preventing the reduction of a thickness of the capping layer 44. Therefore, a desired durability of the capping layer 44 is ensured. In some embodiments, the diffusion barrier layer 42 includes B₄C, BN, BCN, SiN₂, Si₃N₄, SiB₆, SiC, ZrC, ZrN, C, Co, Ir, Zr, RhZr, RuN, HfZr, HfN, NbZr, Nb₄C₃, NbC, NbN, NbSi, the like, or a combination thereof. In some embodiments, the diffusion barrier layer 42 can be formed by physical vapor deposition, atomic layer deposition (ALD), chemical vapor deposition (CVD), ion beam deposition (IBD), or pulsed laser deposition (PLD).

In some embodiments, the diffusion barrier layer 42 has a thickness T1 in a range from 1 nm to 3 nm. If the thickness T1 is less than 1 nm, the diffusion barrier layer 42 may not be thick enough to prevent the interdiffusion between the ML structure 34 and the capping layer 44. If the thickness T1 is greater than 3 nm, the process time of deposition of the diffusion barrier layer 42 may be too long, making the overall deposition process more time consuming and less efficient.

A reflective blank mask B205ca in FIG. 2B is similar to the reflective blank mask B205c in FIG. 2A, except for the ML structure 34a of the reflective blank mask B205ca including a topmost layer 36A made of molybdenum. The diffusion barrier layer 42 having a lower reactivity with the capping layer 44 than the topmost layer 36A of the ML structure 34a, the For example, the diffusion barrier layer 42 is less likely to interdiffuse with the capping layer 44 as compared to the topmost layer 36A of the ML structure 34a. For example, in a heat treatment (e.g., an anneal process), the diffusion barrier layer 42 does not interdiffuse with the capping layer 44. In some embodiments where the capping layer 44 is Ru, the diffusion barrier layer 42 is less likely to diffuse with the capping layer 44 as compared to the topmost layer 36A made of molybdenum. As a result, the interdiffusion between the ML structure 34a and the capping layer 44 can be prevented, thus preventing the reduction of the thickness of the capping layer 44. Therefore, a desired durability of the capping layer 44 is ensured. In some embodiments, the diffusion barrier layer 42 includes B₄C, BN, BCN, SiN₂, Si₃N₄, SiB₆, SiC, ZrC, ZrN, C, Co, Ir, Zr, RhZr, RuN, HfZr, HfN, NbZr, Nb₄C₃, NbC, NbN, NbSi, the like, or a combination thereof. It is noted that silicon is more oxidation resistant than molybdenum. By disposing the diffusion barrier layer 42, the topmost layer of the ML structure 34 can be either silicon or molybdenum, providing increased device design flexibility.

Referring back to FIG. 2A, the reflective blank mask B205c also includes an absorber layer 46 (also referred to as an absorption layer) formed over the capping layer 44. In some embodiments, the absorber layer 46 absorbs the EUV radiation directed onto the EUV mask 205c (see FIG. 1B). In various embodiments, the absorber layer 46 may be made of tantalum boron nitride (TaBN), tantalum boron oxide (TaBO), CrN, or a suitable oxide or nitride (or alloy) of one or more of the following materials: Actium, Radium, Tellurium, Zinc, Copper, and Aluminum. In some embodiments, the absorber layer 46 includes high-k and low refractive index (low-n) materials having a thickness in a range from 30 nm to 100 nm.

FIG. 3 shows an extreme ultraviolet (EUV) mask blank production system. Referring now to FIG. 3, illustrated therein is a schematic top-view diagram of an exemplary EUV mask blank production system 400. In some embodiments, the system 116 may be equivalently referred to as a “cluster tool”. The system 116 may generally include load lock chambers 402, 404, a substrate handling chamber 406, and a plurality of processing chambers C1-C6. In various embodiments, the system 116 may have more or less processing chambers. In some embodiments, the load lock chambers 402 and 404 provide for the transfer of substrates into and out of the system 400. In various embodiments, the system 400 is under vacuum, and the load lock chambers 402 and 404 may “pump down” the wafers introduced into the system 400 (e.g., by way of a mechanical pump and/or a turbomolecular pump). In some embodiments, the load lock chambers 402 and 404 may be adapted to receive a single substrate or a plurality of substrates (e.g., loaded into a cassette). By way of example, the load lock chambers 402 and 404 may be separated from the substrate handling chamber 406 by way of a gate valve, allowing the substrate handling chamber 406 to remain under vacuum when one or both of the load lock chambers 402 and 404 are vented.

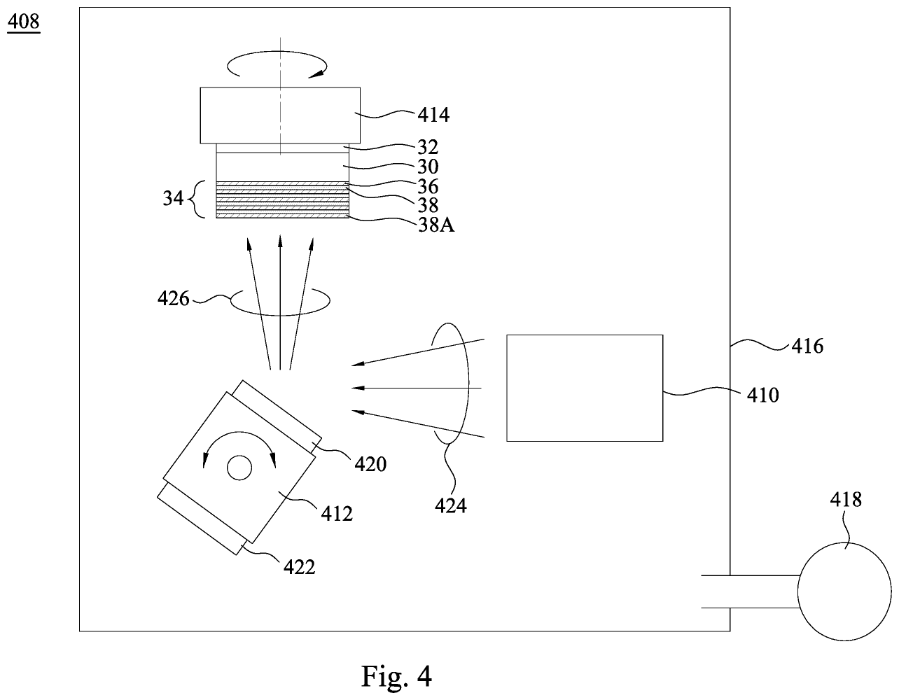

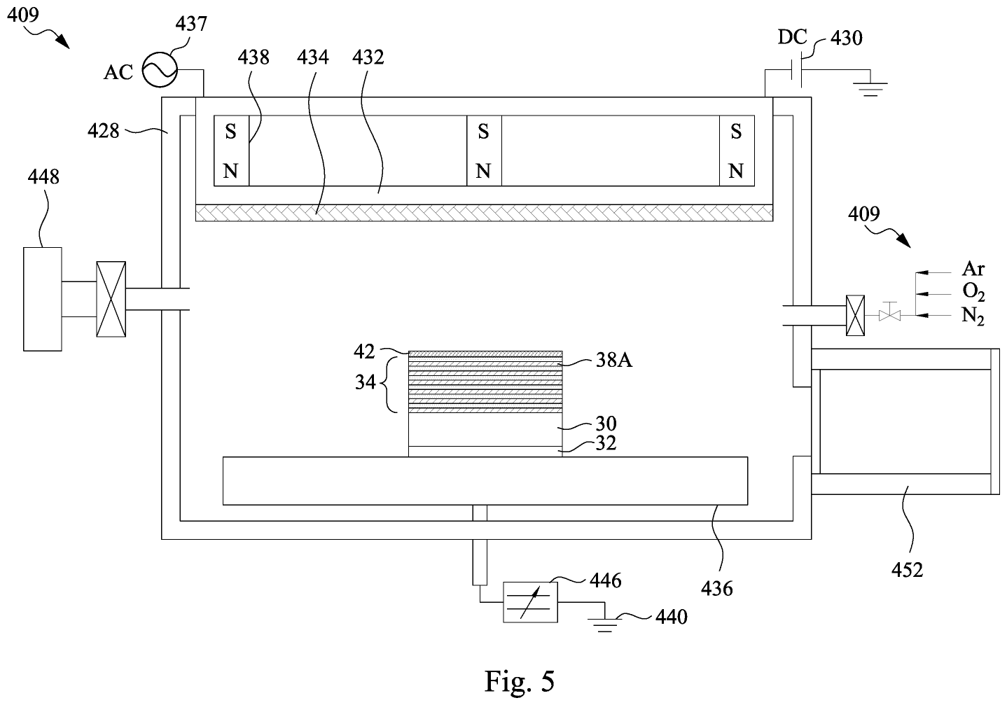

In some embodiments, the substrate handling chamber 406 is equipped with an automated robotic arm RA that may move smoothly along any of a horizontal, vertical, and/or rotational axis so as to transfer wafers between the load lock chambers 402, 404 and any of the substrate processing chambers C1-C6. Each processing chamber C1-C6 may be configured to perform a number of mask processing operations such as ion beam deposition (IBD), sputter deposition, etch process, anneal process, as well as a number of metrology operations such as XPS analysis, AFM analysis, and/or other suitable processing or metrology operations. For example, some of the processing chambers C1-C6 may include an ion beam deposition (IBD) apparatus 408 as shown in FIG. 4 and sputter apparatuses 409, 409a and 409b as shown in FIGS. 5-6 and 8-9, respectively. In some embodiments, the substrate 30 is transferred from one of the processing chambers C1-C6 to the IBD apparatus 408 using the automated robotic arm RA.

FIG. 4 shows an exemplary IBD apparatus 408 in accordance with some embodiments. The substrate 30 is loaded from the substrate handling chamber 406 into the IBD apparatus 408 using the automated robotic arm RA as shown in FIG. 3. Next, the ML structure 34 may be deposited by the use of the IBD apparatus 408 illustrated in FIG. 4. The IBD apparatus 408 illustrated in FIG. 4 includes a sputtering ion source 410, a sputter target supporting member 412, and a substrate supporting member 414. The sputtering ion source 410, the sputter target supporting member 412, and the substrate supporting member 414 are disposed within a vacuum chamber 416. For example, the vacuum chamber 416 is provided with a vacuuming device (vacuum pump) 418 by which the inside of the vacuum chamber 416 can be maintained in a vacuumed state.

The sputter target supporting member 412 holds sputter targets 420 and 422 for deposition of the ML structure 34 at least including two materials (e.g., the silicon and the molybdenum). The sputter target supporting member 412 has a rotation mechanism so that each of the sputter targets 420 and 422 is moved to face the sputtering ion source 410.

The substrate supporting member 414 is faced to the surface of one of the sputter targets 420 and 422. The substrate supporting member 414 has an angle adjusting member (not shown) for positioning the substrate supporting member 414 and the substrate 30 at a predetermined angle with respect to the surface of the one of the sputter targets 420 and 422, and a rotation mechanism (not shown) for rotating the substrate 30 around the rotation axis which is the normal passing through the center of the principal surface of the substrate 30.

In order to deposit the ML structure 34 by ion beam deposition, ions 424 of an inactive gas are extracted from the sputtering ion source 410 and irradiated onto the sputter target 420 (or 422). Then, atoms constituting the sputter target 420 (or 422) are struck and driven out by collision with the ions to generate a target substance 426. At a position faced to the sputter target 420 (or 422), the substrate supporting member 414 with the substrate 30 mounted thereto is located. The target substance 426 is deposited to the substrate 30 to form a thin film layer (one of thin film layers forming the alternate multilayer film of the ML structure 34). For example, the layer 36 of molybdenum is formed in contact with the substrate 30, and then the layer 38 of silicon is formed on the layer 36 of molybdenum.

Next, the sputter target supporting member 412 is rotated to face the other sputter target 422 (or 420) to the sputtering ion source 410. Then, the other thin film layer forming the alternate reflective film of the ML structure 34 is deposited. By alternately repeating the above-mentioned operations, the ML structure 34 including several tens (e.g., 40 pairs of Mo/Si film) or several hundreds of layers is formed on the substrate 30. After the step of forming the ML structure 34 is finished, the ML structure 34 has the topmost layer 38A made of silicon.

Reference is made to FIG. 5. The substrate 30 is then transferred to the sputter apparatus 409 in one of the processing chambers C1-C6 using the automated robotic arm RA. In greater detail, after performing the ion beam deposition on the substrate 30 to form the ML structure 34 using the IBD apparatus 408 in one of the processing chambers C1-C6, the automated robotic arm RA transfers the substrate 30 to the sputter apparatus 409 in another one of the processing chambers C1-C6.

FIG. 5 shows an exemplary sputter apparatus 409 in accordance with some embodiments. The sputter apparatus 409 includes a vacuum chamber 428, a high voltage DC power source 430, a backing plate 432 configured to hold a target 434, and a pedestal 436 configured to hold the substrate 30. The backing plate 432 is coupled to the high voltage DC power source 430 whereby the target 434 may act as a cathode for a glow discharge between target 434 and the substrate 30. The backing plate 432 is also coupled to a radio frequency (RF) power source 437. The sputtering apparatus 409 is a magnetron sputtering system and includes magnets 438 behind the backing plate 432. The substrate 30 is coupled to ground 440 through pedestal 436 and a variable capacitor 446. The substrate 30 on the pedestal 436 provides an anode. A vacuum pumping system 448 is operative to evacuate the vacuum chamber 428. A process gas supply 450 may be used to introduce process gases into the vacuum chamber 428. A load lock system 452 may be used to introduce or remove the substrate 30 from the vacuum chamber 428 while the vacuum chamber 428 remains at sub-atmospheric pressure.

The target 434 includes the material to be deposited. For example, the target 434 includes the material of the diffusion barrier layer 42. A glow discharge between the cathode and the anode generates a plasma of positive ions from the process gas. The positive ions accelerate toward and bombard the target 434 causing atoms of the material of the target 434 to be ejected. Some of the ejected atoms deposit on a surface (e.g, on the topmost layer 38A made of silicon) of the ML structure 34 over the substrate 30 to form a thin film of the material of the target 434. The sputter gas ions are typically argon ions, or ions from another inert gas. However, some embodiments of the sputter apparatus 409 may implement reactive operations such as O₂ and N₂ processes for oxides and nitrides. Other embodiments of the sputter apparatus 409 may include additional components or features known in the art. The diffusion barrier layer 42 is in contact with the topmost layer 38A made of silicon.

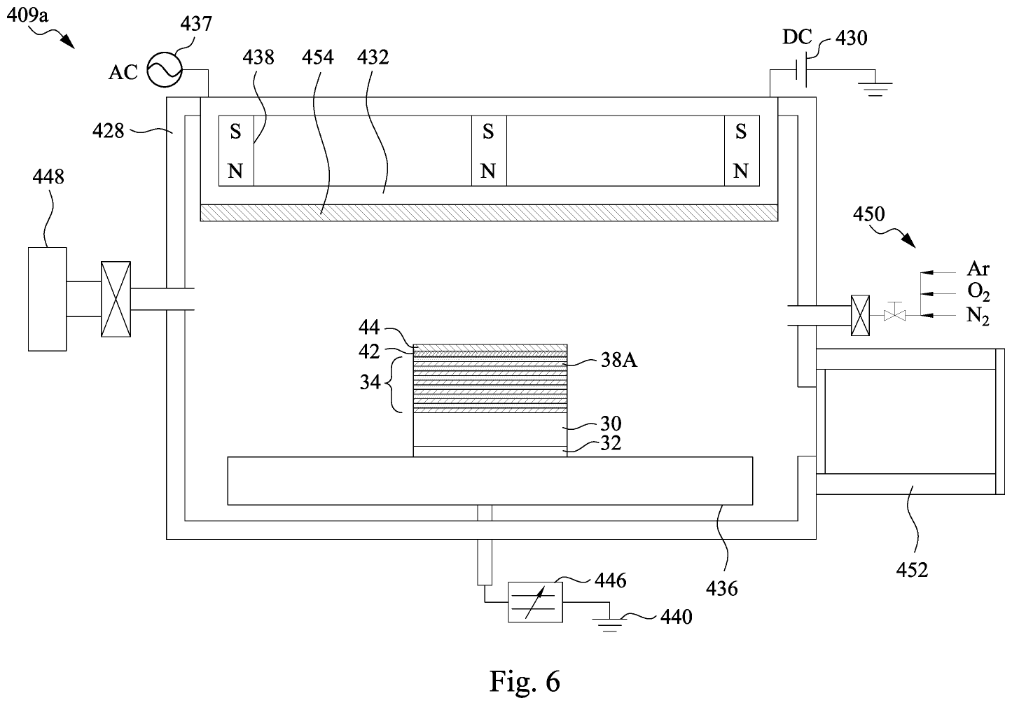

Referring to FIG. 6, after the formation of the diffusion barrier layer 42, the substrate 30 is transferred to a sputter apparatus 409a in one of the processing chambers using the automated robotic arm RA. In greater detail, after performing the sputter deposition process on the substrate 30 to form the diffuse barrier layer 42 using the sputter apparatus 409 in one of the processing chambers C1-C6, the automated robotic arm RA transfers the substrate 30 to the sputter apparatus 409a in another one of the processing chambers C1-C6. As shown in FIG. 6, the capping layer 44 is formed overlying the diffusion barrier layer 42 by sputter deposition using the sputter apparatus 409a. In an implement where the capping layer includes Ru, the diffusion barrier layer 42 is exposed to an Ru-based sputter target 454 when the substrate 30 with the overlying diffusion barrier layer 42 is loaded into the vacuum chamber 428 of the sputter apparatus 409a. In an example, the Ru-based sputter target 454 contains 99.999% pure Ru material.

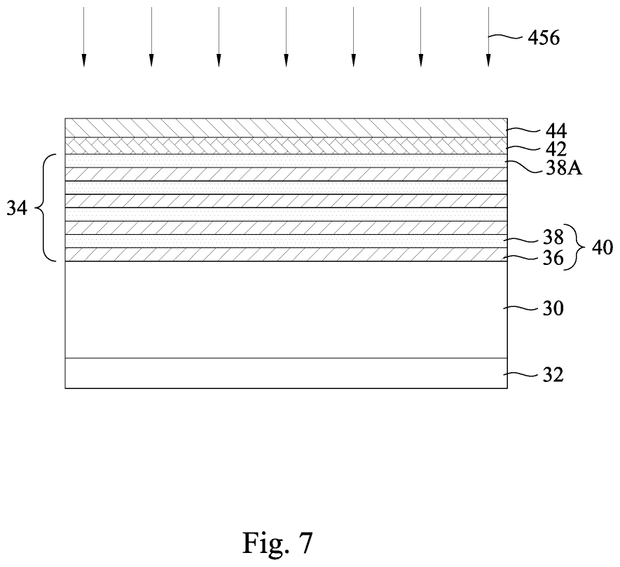

In some embodiments, after forming the capping layer 44, the substrate 30 may be transferred to an anneal system in one of the processing chambers C1-C6 or stay in the vacuum chamber 428 capable of performing anneal process. In FIG. 7, a post-deposition anneal process 456 is performed prior to the formation of the absorber layer 46 to reduce stress and the deterioration of flatness in the stacked layers on the substrate 30. Since the diffusion barrier layer 42 is present between the capping layer 44 and the ML structure 34, interdiffusion between the capping layer 44 and the ML structure 34 during the post-deposition anneal process 456 can be prevented, thereby preventing reduction of the thickness of the capping layer 44. In other words, the capping layer 44 is substantially unchanged in thickness before and after the post-deposition anneal process 456.

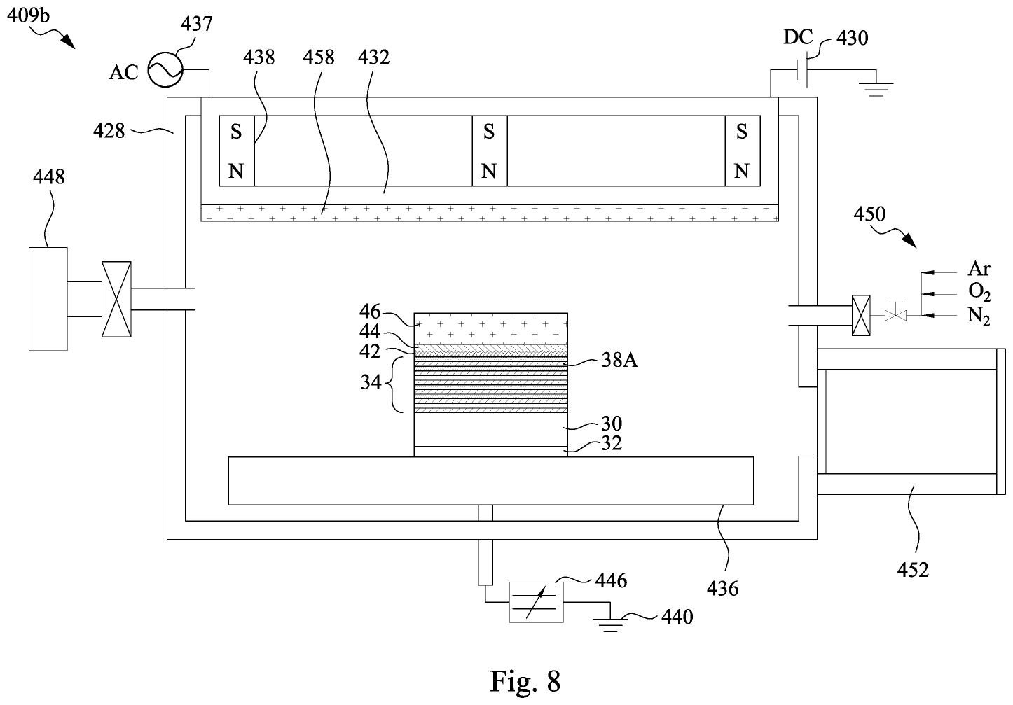

Referring to FIG. 8, after performing the post-deposition anneal process 456, the substrate 30 is transferred to a sputter apparatus 409b in one of the processing chambers using the automated robotic arm RA. As shown in FIG. 8, the absorber layer 46 is formed overlying the capping layer 44 by sputter deposition using the sputter apparatus 409b. In an implement where the absorber layer 46 includes TaBN, the capping layer 44 is exposed to a TaB-based sputter target 458 under Ar—N₂ plasma when the substrate 30 with the overlying capping layer 44 is loaded into the vacuum chamber 428 of the sputter apparatus 409b. In an example, the TaBO-based sputter target 454 contains 99.999% pure Ru material.

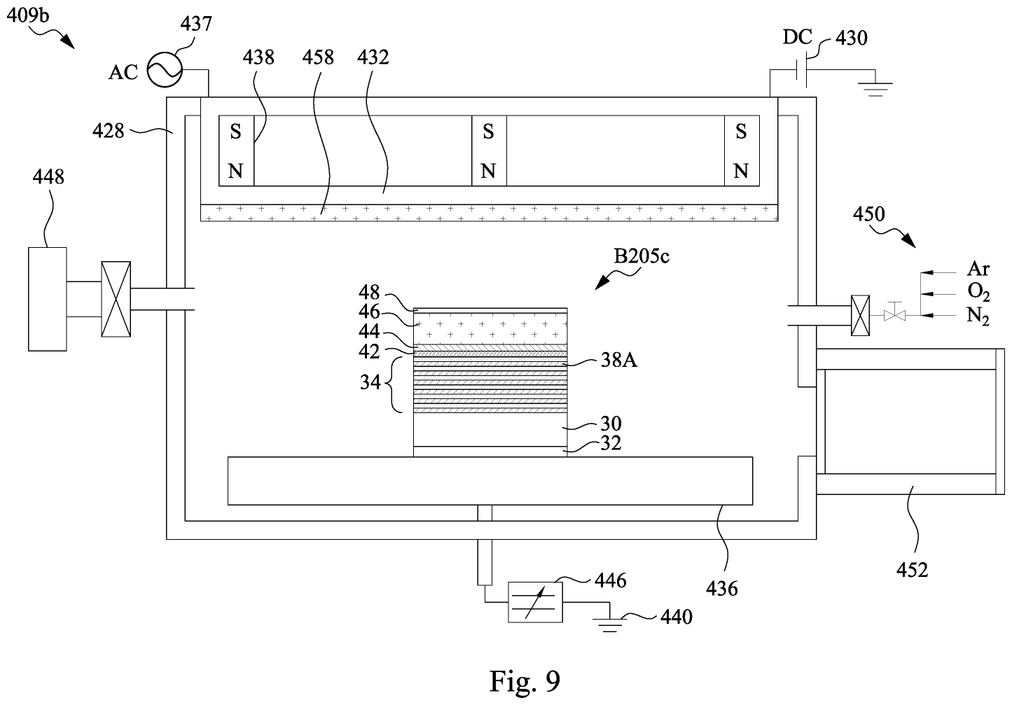

In FIG. 9, after the deposition of the absorber layer 46, in an implement, an anti-reflection layer 48 is deposited over the absorber layer 46 using a sputter deposition process. Thus, the EUV photo mask blank B205c is formed. The anti-reflection layer 48 reduces reflections of photolithographic radiation. In some embodiments, after the deposition of the absorber layer 46, the substrate 30 stays in the sputter apparatus 409b. For example, in some embodiments where the anti-reflection layer 48 includes TaBO, the absorber layer 46 is exposed to the TaB-based sputtering target 458 under Ar—O₂ plasma in the vacuum chamber 428 of the sputter apparatus 409b. In some other embodiments, the substrate 30 may be transferred to another sputter deposition apparatus in one of the processing chambers C1-C6 to deposit the anti-reflection layer 48. The anti-reflection layer 48 may be formed of a material including SiO₂, SiN, TaOs, Cr₂O₃, ITO (indium tin oxide), or any suitable material, in some embodiments of the present disclosure.

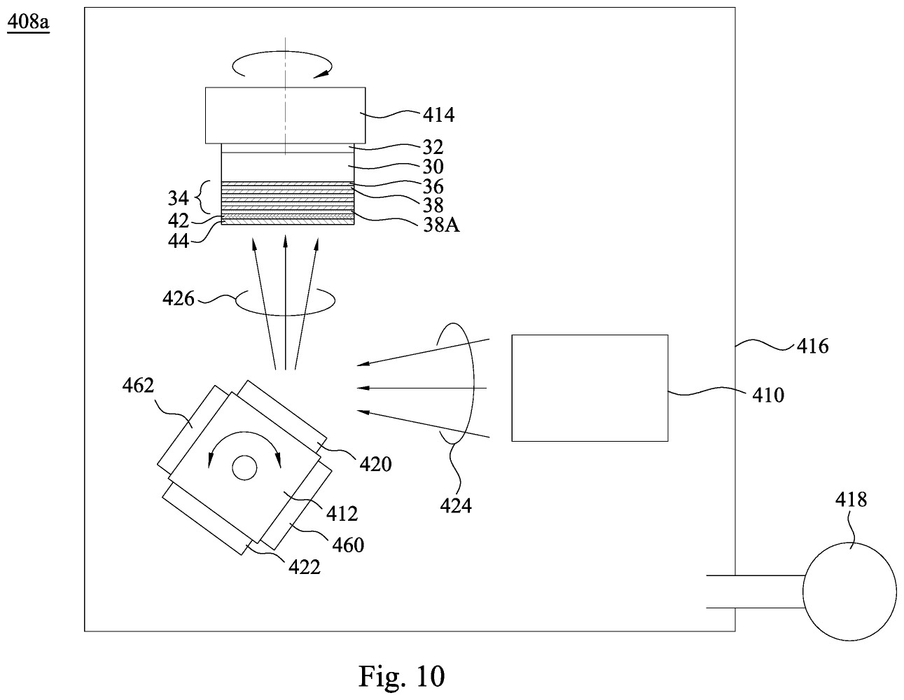

FIGS. 10-13 show cross-sectional views of fabrication of the EUV blank mask at various stages in accordance with some other embodiments. In this case, the depositions of the ML structure 34 and the diffusion barrier layer 42 are performed in the same chamber (e.g., in the vacuum chamber 416 of the IBD apparatus 408a). FIG. 10 shows an exemplary IBD apparatus 408a in accordance with some embodiments. The substrate 30 is loaded from the substrate handling chamber 406 into the IBD apparatus 408a using the automated robotic arm RA as shown in FIG. 3. The IBD apparatus 408a is similar to the IBD apparatus 408 in FIG. 4, except for the sputter target supporting member 412 further holding a sputter target 460 for deposition of the diffusion barrier layer 42 and a sputter target 462 for deposition of the capping layer 44.

First, the ML structure 34 is formed on the substrate 30 by IBD in the IBD apparatus 408a, as discussed previously with regard to FIG. 4. The detail description thereof is omitted herein. After the ML structure 34 is formed, ions 424 of an inactive gas are extracted from the sputtering ion source 410 and irradiated onto the sputter target 460. Then, atoms constituting the sputter target 460 are struck and driven out by collision with the ions to generate the target substance 426. The target substance 426 is deposited to the substrate 30 to form a thin film layer of the diffusion barrier layer 42.

Next, the sputter target supporting member 412 is rotated to face the other sputter target 462 to the sputtering ion source 410. Then, the other thin film forming the capping layer 44 is deposited.

In some embodiments, after forming the capping layer 44, the substrate 30 may be transferred to an anneal system in one of the processing chambers C1-C6 or stay in the IBD apparatus 408a capable of performing anneal process. A post-deposition anneal process 456 is performed prior to the formation of the absorber layer 46 to reduce stress and the deterioration of flatness in the stacked layers on the substrate 30. Since the diffusion barrier layer 42 is present between the capping layer 44 and the ML structure 34, interdiffusion between the capping layer 44 and the ML structure 34 during the post-deposition anneal process 456 can be prevented, thereby preventing reduction of the thickness of the capping layer 44.

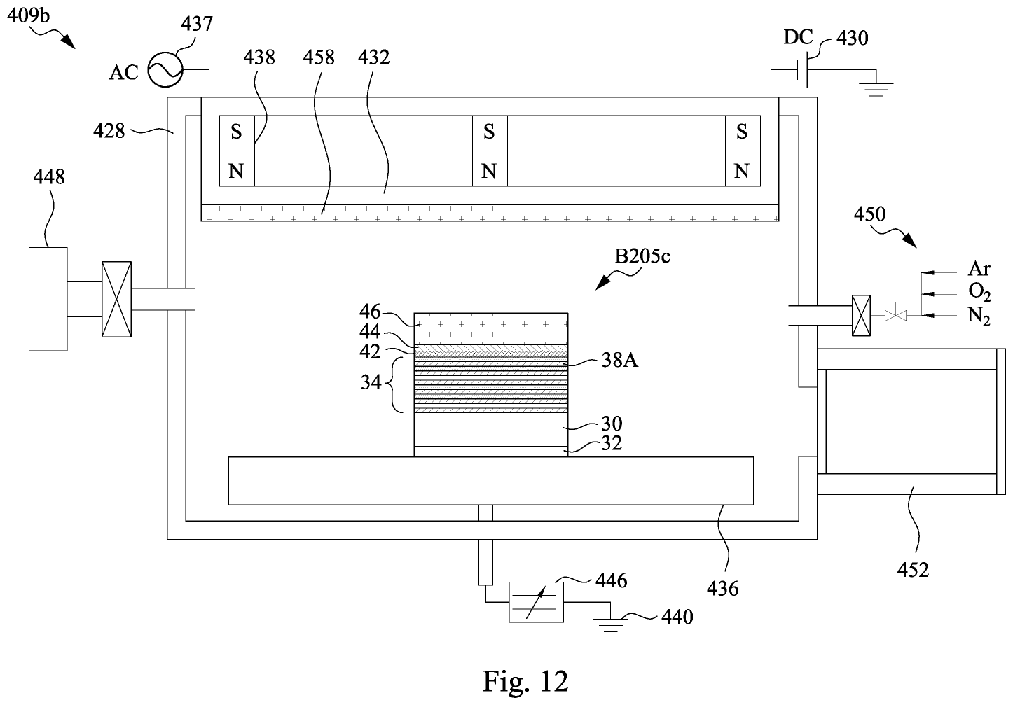

Referring to FIG. 12, after the post-deposition anneal process 456 is performed, the substrate 30 is transferred to the sputter apparatus 409b in one of the processing chambers C1-C6 using the automated robotic arm RA, as discussed previously with regard to FIG. 8. An absorber layer 46 is formed over the capping layer 44 by sputter deposition process using the sputter apparatus 409b. The detail description thereof is omitted herein.

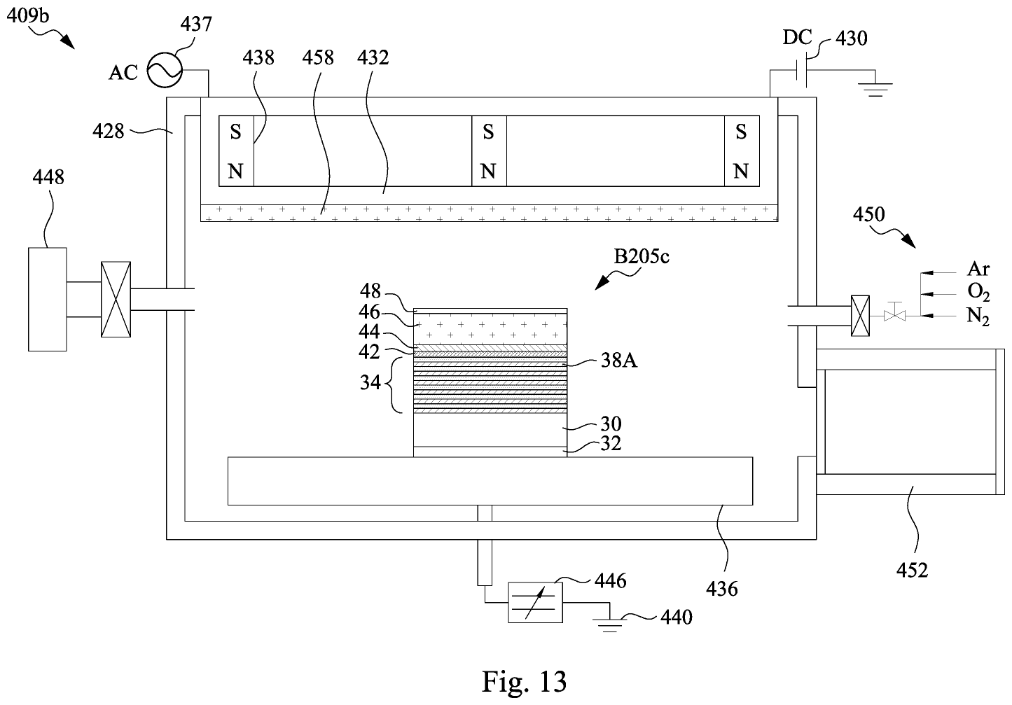

Referring to FIG. 12, after the post-deposition anneal process 456 is performed, the substrate 30 is transferred to the sputter apparatus 409b in one of the processing chambers C1-C6 using the automated robotic arm RA, as discussed previously with regard to FIG. 8. As shown in FIG. 12, the absorber layer 46 is deposited overlying the capping layer 44 by sputter deposition using the sputter apparatus 409b. The detail description thereof is omitted herein. In FIG. 13, after the deposition of the absorber layer 46, in an implement, the substrate 30 may stay in the sputter apparatus 409b, as discussed previously with regard to FIG. 9. An anti-reflection layer 48 is then deposited over the absorber layer 46 by a sputter deposition process using the sputter apparatus 409b. The detail description thereof is omitted herein. Thus, the EUV photo mask blank B205c is formed. The detail description thereof is omitted herein. In some other embodiments, the substrate 30 may be transferred to another sputter deposition apparatus in one of the processing chambers C1-C6.

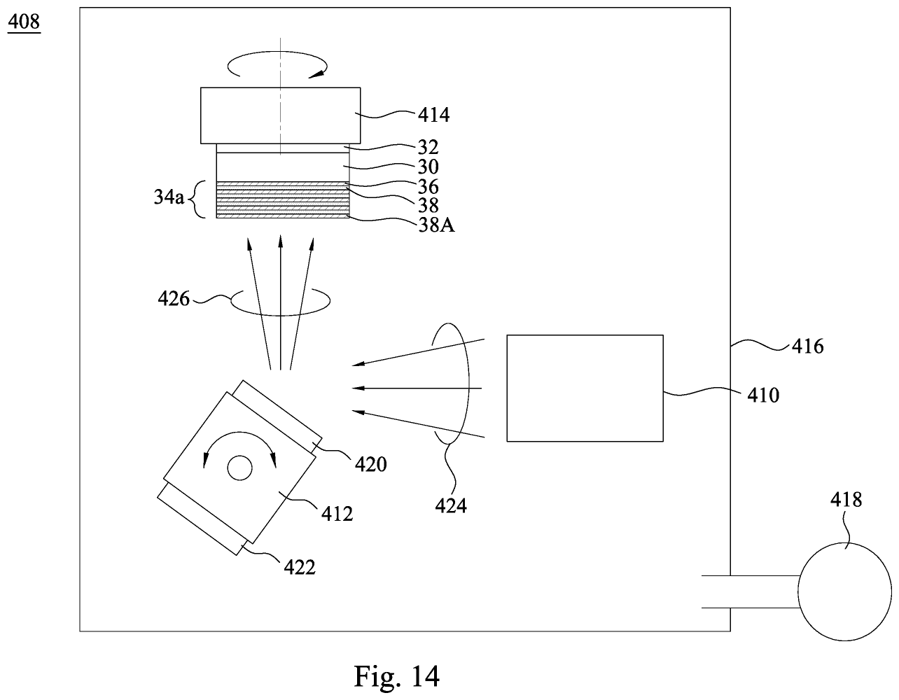

FIGS. 14-19 show cross-sectional views of fabrication of the EUV blank mask B205ca at various stages in accordance with some other embodiments. FIG. 14 shows the exemplary IBD apparatus 408 in accordance with some embodiments. The substrate 30 is loaded from the substrate handling chamber 406 into the IBD apparatus 408 using the automated robotic arm RA as shown in FIG. 3. Next, the ML structure 34a may be deposited by the use of the IBD apparatus 408 illustrated in FIG. 4. The formation method of ML structure 34a is similar to the formation method of the ML structure 34 as discussed previously with regard to FIG. 4, except for the ML structure 34a including the topmost layer 36A made of molybdenum. That is, after the step of forming the ML structure 34a is finished, the ML structure 34a has the topmost layer 36A made of molybdenum.

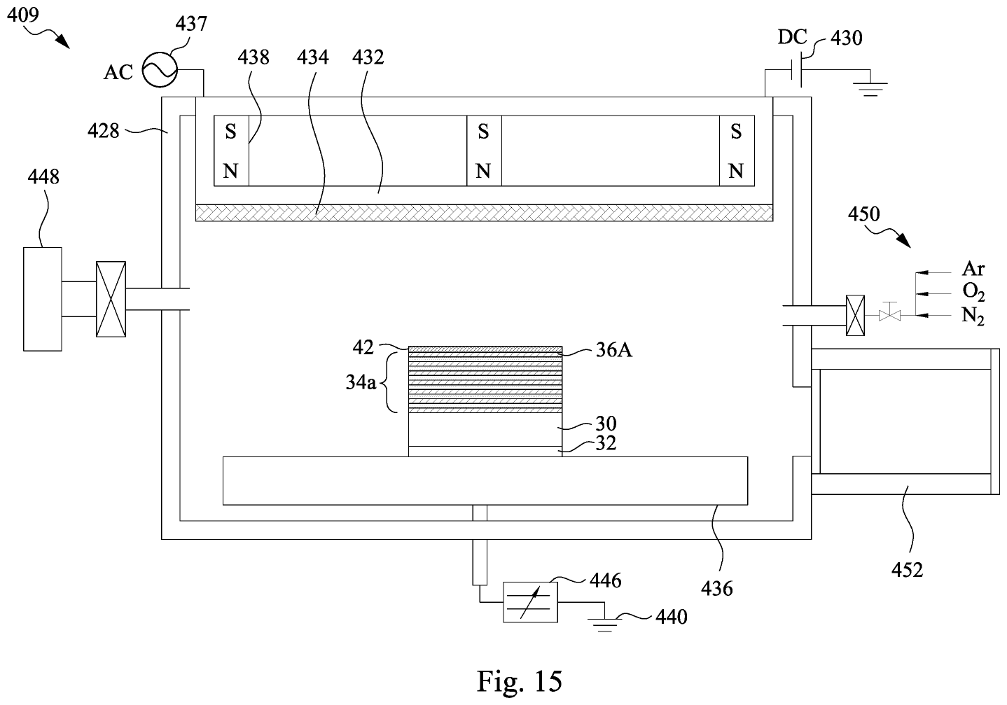

Reference is made to FIG. 15. The substrate 30 is transferred to the sputter apparatus 409 in one of the processing chambers C1-C6 using the automated robotic arm RA. The diffusion barrier layer 42 can be deposited over the ML structure 34a by a sputter deposition process using the sputter apparatus 409, as discussed previously with regard to FIG. 5, except for the diffusion barrier layer 42 being in contact with the topmost layer 36A made of molybdenum.

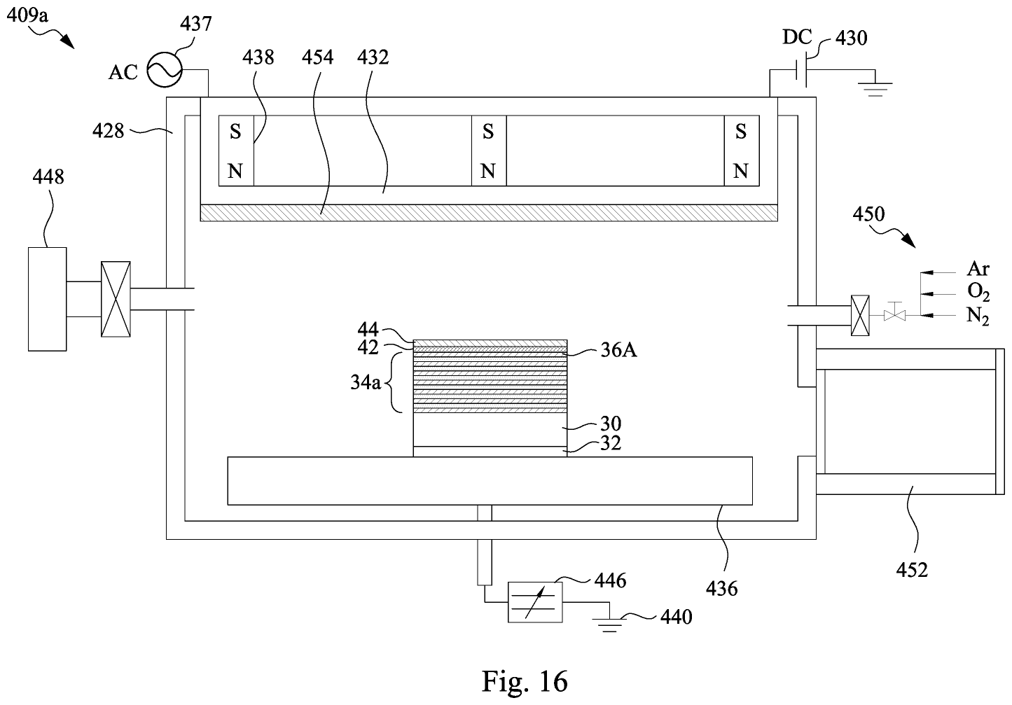

Reference is made to FIG. 16. The substrate 30 is transferred to the sputter apparatus 409a in one of the processing chambers C1-C6 using the automated robotic arm RA. The capping layer 44 can be deposited over the diffusion barrier layer 42 by a sputter deposition process using the sputter apparatus 409a, as discussed previously with regard to FIG. 6.

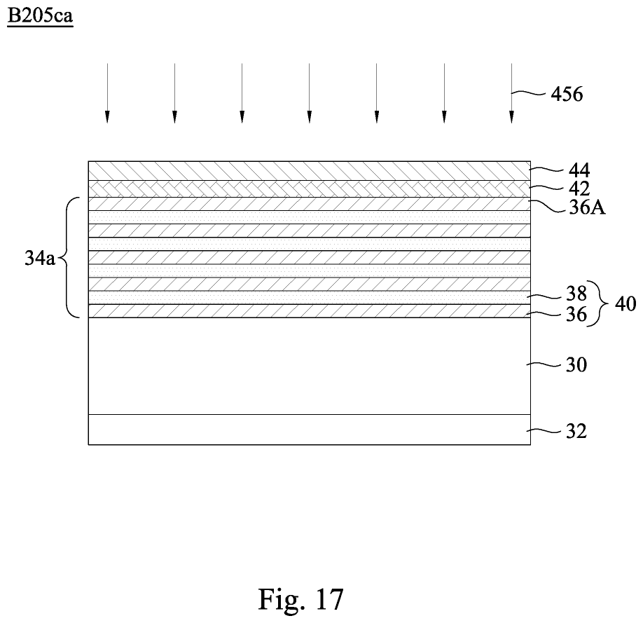

In FIG. 17, in some embodiments, after forming the capping layer 44, the substrate 30 may be transferred to an anneal system in one of the processing chambers C1-C6 or stay in the IBD apparatus 408a capable of performing anneal process. A post-deposition anneal process 456 is performed prior to the formation of a subsequently formed absorber layer 46 to reduce stress and the deterioration of flatness in the stacked layers on the substrate 30. Since the diffusion barrier layer 42 is present between the capping layer 44 and the ML structure 34, interdiffusion between the capping layer 44 and the topmost layer 38a of the ML structure 34 during the post-deposition anneal process 456 can be prevented, thereby preventing reduction of the thickness of the capping layer 44.

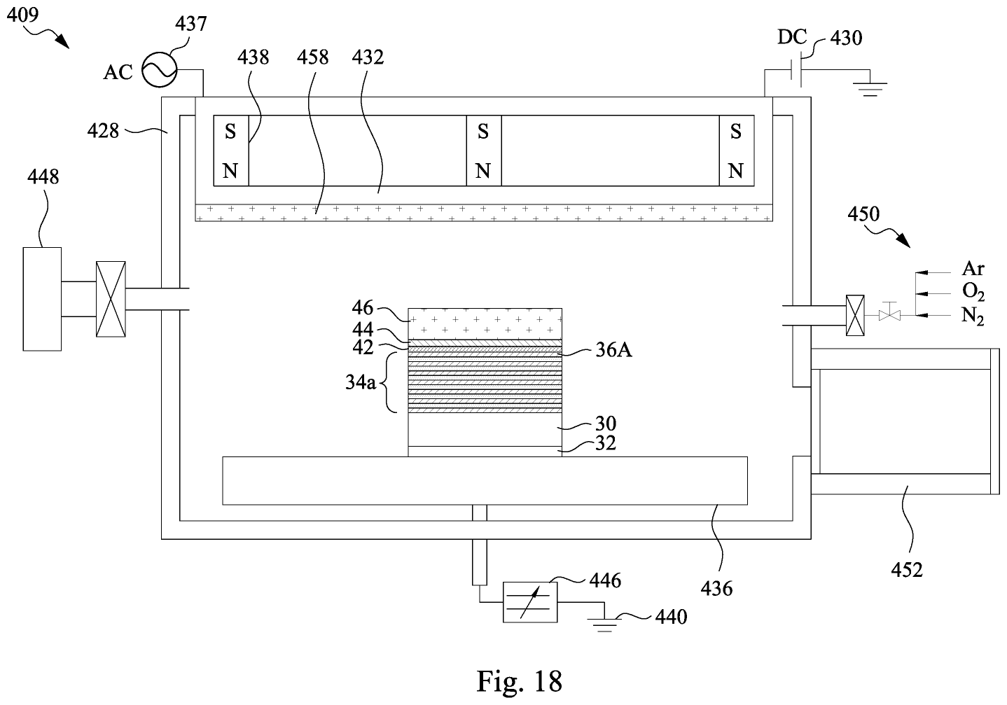

Referring to FIG. 18, after the post-deposition anneal process 456 is performed, the substrate 30 is transferred to the sputter apparatus 409b in one of the processing chambers C1-C6 using the automated robotic arm RA, as discussed previously with regard to FIG. 8. An absorber layer 46 is formed over the capping layer 44 by sputter deposition process using the sputter apparatus 409b. The detail description thereof is omitted herein.

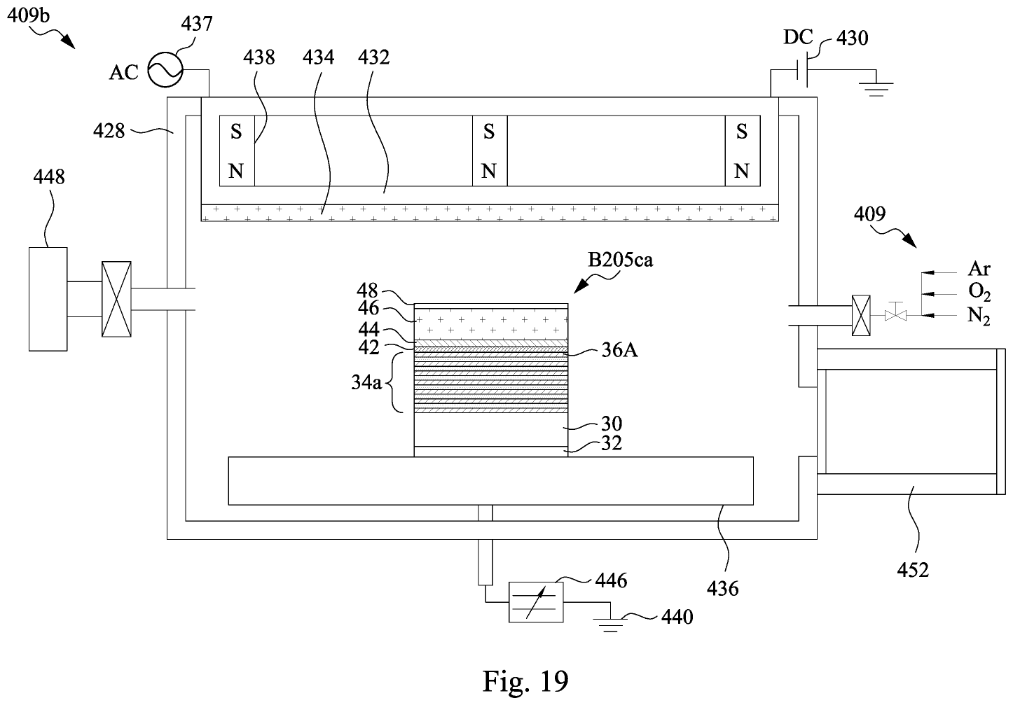

Referring to FIG. 19, an anti-reflection layer 48 is then deposited over the absorber layer 46 by a sputter deposition process using the sputter apparatus 409b. Thus, the EUV photo mask blank B205ca is formed. The detail description thereof is omitted herein. In some other embodiments, the substrate 30 may be transferred to another sputter deposition apparatus in one of the processing chambers C1-C6.

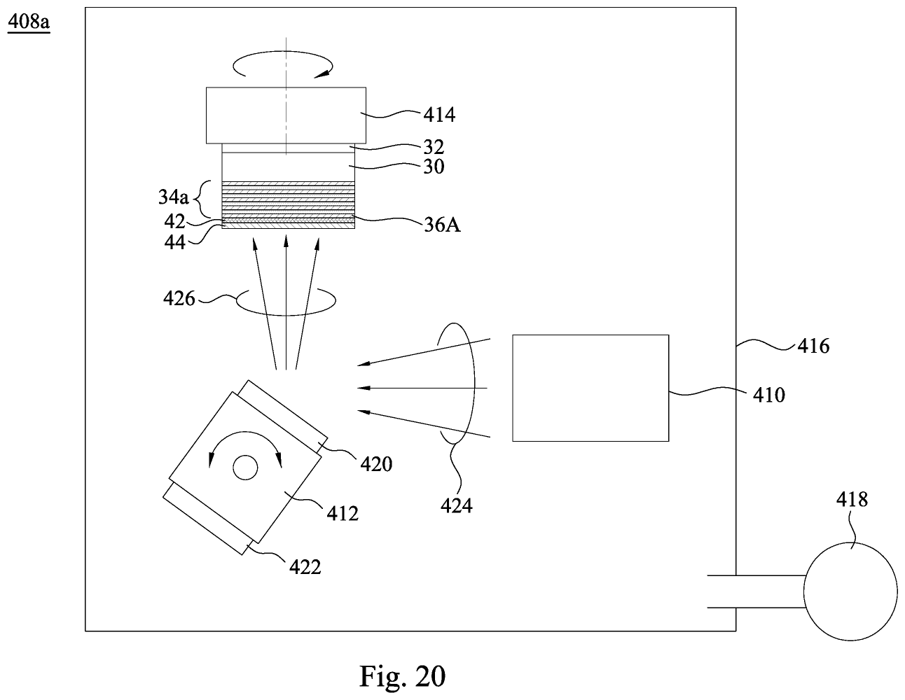

FIGS. 20-23 show cross-sectional views of fabrication of the EUV blank mask at various stages in accordance with some other embodiments. FIG. 20 shows the exemplary IBD apparatus 408a in accordance with some embodiments. The substrate 30 is loaded from the substrate handling chamber 406 into the IBD apparatus 408a using the automated robotic arm RA as shown in FIG. 3. The IBD apparatus 408a is similar to the IBD apparatus 408 in FIG. 4, except for the sputter target supporting member 412 further holding the sputter target 460 for deposition of the diffusion barrier layer 42 and the sputter target 462 for deposition of the capping layer 44.

Firstly, the ML structure 34a is formed on the substrate 30 by IBD in the IBD apparatus 408a, as discussed previously with regard to FIG. 4. The detail description thereof is omitted herein. After the ML structure 34a is formed, the ML structure 34a has the topmost layer 36A made of molybdenum. Ions 424 of an inactive gas are extracted from the sputtering ion source 410 and irradiated onto the sputter target 460. Then, atoms constituting the sputter target 460 are struck and driven out by collision with the ions to generate the target substance 426. The target substance 426 is deposited to the substrate 30 to form a thin film layer of the diffusion barrier layer 42. The diffusion barrier layer 42 is in contact with the topmost layer 36A made of molybdenum.

Next, the sputter target supporting member 412 is rotated to face the other sputter target 462 to the sputtering ion source 410. Then, the other thin film forming the capping layer 44 is deposited.

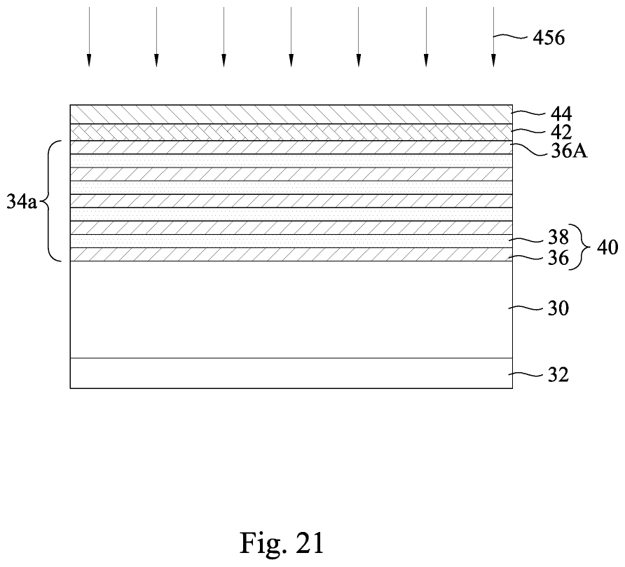

In FIG. 21, in some embodiments, after forming the capping layer 44, the substrate 30 may be transferred to an anneal system in one of the processing chambers C1-C6 or stay in the IBD apparatus 408a capable of performing anneal process. A post-deposition anneal process 456 is performed prior to the formation of the absorber layer 46 to reduce stress and the deterioration of flatness in the stacked layers on the substrate 30. Since the diffusion barrier layer 42 is present between the capping layer 44 and the ML structure 34a, interdiffusion between the capping layer 44 and the topmost layer 36A of the ML structure 34a during the post-deposition anneal process 456 can be prevented, thereby preventing reduction of the thickness of the capping layer 44.

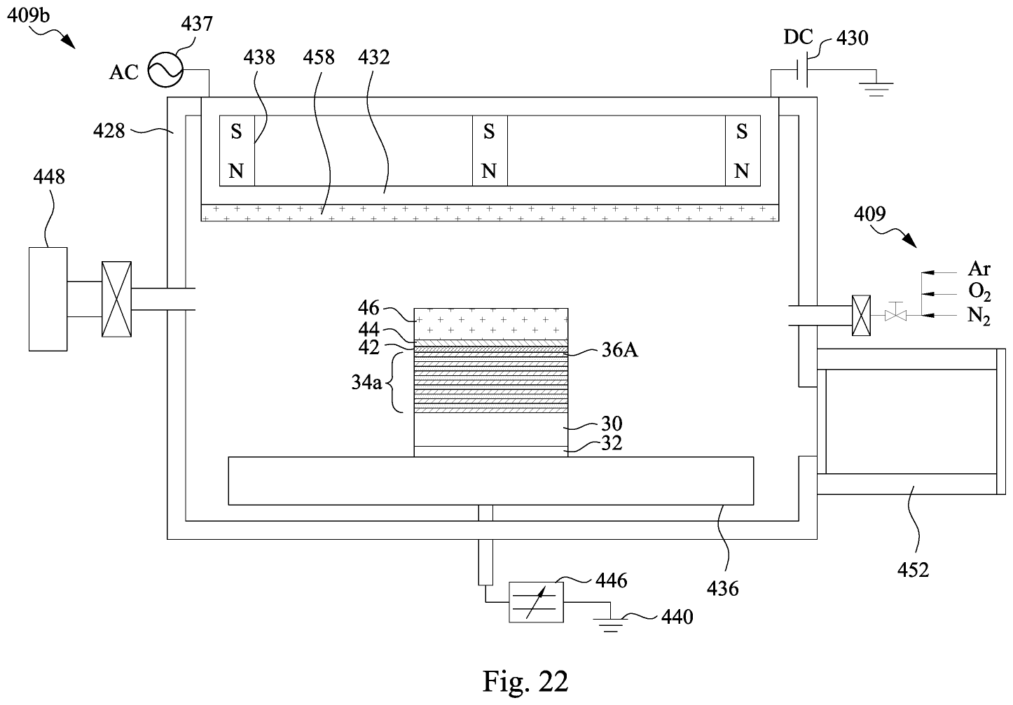

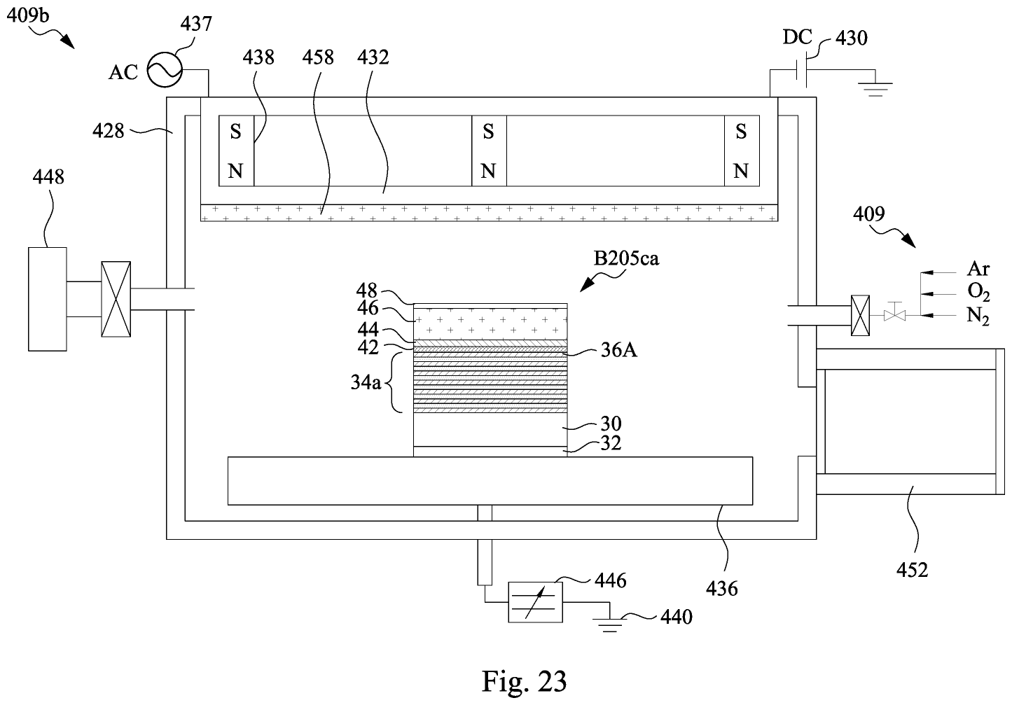

Referring to FIG. 22, after performing the post-deposition anneal process 456, the substrate 30 is transferred to the sputter apparatus 409b in one of the processing chambers C1-C6 using the automated robotic arm RA, as discussed previously with regard to FIG. 8. As shown in FIG. 8, the absorber layer 46 is formed overlying the capping layer 44 by sputter deposition using the sputter apparatus 409b. The detail description thereof is omitted herein. In FIG. 23, after the deposition of the absorber layer 46, in an implement, the substrate 30 stays in the sputter apparatus 409b, as discussed previously with regard to FIG. 9. An anti-reflection layer 48 is then deposited over the absorber layer 46 by sputter deposition process using the sputter apparatus 409b. Thus, the EUV photo mask blank B205ca is formed. The detail description thereof is omitted herein. In some other embodiments, the substrate 30 may be transferred to another sputter deposition apparatus in one of the processing chambers C1-C6 to deposit the anti-reflection layer 48.

Reference is made to FIG. 24A. One or more circuit patterns 50 are formed on the EUV photo mask blank B205c (see FIG. 2A) by performing an etching step to pattern the absorber layer 46 and the anti-reflection layer 48, forming the patterned absorber layer 46 and patterned anti-reflection layer 48. Thus, an EUV mask 205c is formed. In some embodiments, the etching step is performed using a chloride-based or fluoride-based dry etching followed by applying sulfuric peroxide mixture (SPM) cleaning solution. In other words, the SPM cleaning solution is applied on the absorber layer 46 after performing the chlorine-based or fluorine-based dry etching. In some embodiments, the SPM cleaning solution includes a mixture of sulfuric acid, a hydrogen peroxide solution, and pure water. In some embodiments, the etching step is performed using electron beam demonstrated on the EUV photo mask blank by using NOCl₁ (e.g., NOCl₂), a rare-based gas such as neon dioxide, or the like, as precursor gas. As discussed previously with regard to FIG. 2A, since the reduction of the thickness of the capping layer 44 is prevented by disposing the diffusion barrier layer between the capping layer 44 and the ML structure 34, the capping layer 44 is strong enough to sustain the etching step, preventing durability issues of the capping layer 44.

The EUV mask 205c is a reflective mask, and the ML structure 34 reflects the EUV light, while the absorber layer 46 absorbs the EUV light. During the patterning, the absorber layer 46 and the anti-reflection layer 48 are partially removed. For example, the absorber layer 46 is etched to expose the capping layer 44. In addition, a black border area 52 surrounding the circuit patterns 50 and penetrating to the substrate 30 is formed. The circuit patterns 50 are formed by using one or more lithography (e.g., electron beam lithography) and etching operations. In some examples, the area in which no circuit pattern is formed is covered by an absorber layer 46 so that the EUV light is not reflected.

FIG. 24B is similar to FIG. 24A, except for the ML structure 34a of the EUV mask 205ca including a topmost layer 36A made of molybdenum. As discussed previously with regard to FIG. 2A, since the reduction of the thickness of the capping layer 44 is prevented by disposing the diffusion barrier layer between the capping layer 44 and the ML structure 34, the capping layer 44 is strong enough to sustain the etching step, preventing durability issues of the capping layer 44.

FIG. 25 shows a flowchart illustrating a method S100 of extreme ultraviolet lithography (EUVL) according to an embodiment of the present disclosure. In some embodiments, the method S100 is performed by the computer system 900 of FIGS. 26A and 26B. The method S100 includes an operation S102 of generating plasma in an EUV lithography system. The EUV lithography system forms a projection beam of EUV radiation using EUV radiation emitted from a radiation source. In operation S104, an EUV mask including the diffusion barrier layer disposed between the ML structure and the capping layer is exposed to the projection beam of EUV radiation. The capping layer is strong enough to sustain the etching step, preventing durability issues of the capping layer. In operation S106, a photoresist coated semiconductor wafer is exposed to the projection beam of EUV radiation reflecting off the EUV mask. Operation S102 is triggered by turning on the laser source 300 and the droplet generator 115 as illustrated in FIG. 1A, and the operations S104 and S106 occur naturally once the operation S102 is triggered, as long as the optics 205a-205e are suitably oriented to direct the EUV projection beam.

FIGS. 26A and 26B show a photo mask data generating apparatus according to an embodiment of the present disclosure. FIG. 26A is a schematic view of a computer system that executes the photo mask data generating process according to one or more embodiments as described above. All of or a part of the process, method and/or operations of the foregoing embodiments can be realized using computer hardware and computer programs executed thereon. In FIG. 26A, a computer system 900 is provided with a computer 901 including an optical disk read only memory (e.g., CD-ROM or DVD-ROM) drive 905 and a magnetic disk drive 906, a keyboard 902, a mouse 903, and a monitor 904.

FIG. 26B is a diagram showing an internal configuration of the computer system 900. In FIG. 26B, the computer 901 is provided with, in addition to the optical disk drive 905 and the magnetic disk drive 906, one or more processors 911, such as a micro processing unit (MPU), a ROM 912 in which a program such as a boot up program is stored, a random access memory (RAM) 913 that is connected to the MPU 911 and in which a command of an application program is temporarily stored and a temporary storage area is provided, a hard disk 914 in which an application program, a system program, and data are stored, and a bus 915 that connects the MPU 911, the ROM 912, and the like. Note that the computer 901 may include a network card (not shown) for providing a connection to a LAN.

The program for causing the computer system 900 to execute the functions of the photo mask data generating apparatus in the foregoing embodiments may be stored in an optical disk 921 or a magnetic disk 922, which are inserted into the optical disk drive 905 or the magnetic disk drive 906, and transmitted to the hard disk 914. Alternatively, the program may be transmitted via a network (not shown) to the computer 901 and stored in the hard disk 914. At the time of execution, the program is loaded into the RAM 913. The program may be loaded from the optical disk 921 or the magnetic disk 922, or directly from a network.

The program does not necessarily have to include, for example, an operating system (OS) or a third party program to cause the computer 901 to execute the functions of the photo mask data generating apparatus in the foregoing embodiments. The program may only include a command portion to call an appropriate function (module) in a controlled mode and obtain desired results.

In the programs, the functions realized by the programs do not include functions that can be realized only by hardware in some embodiments. For example, functions that can be realized only by hardware, such as a network interface, in an acquiring unit that acquires information or an output unit that outputs information are not included in the functions realized by the above-described programs in some embodiments. Furthermore, a computer that executes the programs may be a single computer or may be multiple computers.

Further, the entirety of or a part of the programs to realize the functions of the photo mask data generating apparatus is a part of another program used for photo mask fabrication processes in some embodiments. In addition, the entirety of or a part of the programs to realize the functions of the photo mask data generating apparatus is realized by a ROM made of, for example, a semiconductor device in some embodiments.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that by disposing the diffusion barrier layer between the ML structure and the capping layer, the interdiffusion between the ML structure and the capping during the anneal process can be prevented, thus preventing the reduction of the thickness of the capping layer. Another advantage is that since the reduction of the thickness of the capping layer is prevented, the capping layer is strong enough to sustain the etching step, preventing durability issues of the capping layer.

In some embodiments, an extreme ultraviolet (EUV) mask includes a substrate, a reflective multilayer stack on the substrate, a diffusion barrier layer, a capping layer and a patterned absorber layer. The reflective multilayer stack comprises alternately stacked first layers and second layers. The diffusion barrier layer is on the reflective multilayer stack. The diffusion barrier layer has a composition different from compositions of the first layers and the second layers. The capping layer is on the diffusion barrier layer. The patterned absorber layer is on the reflective multilayer stack. In some embodiments, the diffusion barrier layer has a lower reactivity with the capping layer than the reflective multilayer stack. In some embodiments, the diffusion barrier layer is free from Ru. In some embodiments, the diffusion barrier layer is free from molybdenum. In some embodiments, the diffusion barrier layer comprises B₄C, BN, BCN, SiN₂, Si₃N₄, SiB₆, SiC, ZrC, ZrN, C, Co, Ir, Zr, RhZr, RuN, HfZr, HfN, NbZr, Nb₄C₃, NbC, NbN, NbSi, or a combination thereof. In some embodiments, diffusion barrier layer has a thickness in a range from 1 nm to 3 nm. In some embodiments, the reflective multilayer stack includes a topmost layer made of molybdenum, and the diffusion barrier layer is in contact with the topmost layer. In some embodiments, the reflective multilayer stack includes a topmost layer made of silicon, and the diffusion barrier layer is in contact with the topmost layer.

In some embodiments, a method of forming an EUV mask includes performing a first deposition process to form a reflective multilayer stack over a substrate, the reflective multilayer stack comprising alternating stacked molybdenum layer and silicon layers, performing a second deposition process to form a diffusion barrier layer on the reflective multilayer stack, forming a capping layer on the diffusion barrier layer, wherein the diffusion barrier has a lower reactivity with the capping layer than the reflective multilayer stack, performing an anneal process after forming the capping layer, forming an absorber layer on the capping layer, and etching the absorber layer to form a pattern in the absorber layer. In some embodiments, the diffusion barrier layer does not react with the capping layer during the anneal process. In some embodiments, the first deposition process and the second deposition process are performed in a same chamber. In some embodiments, the first deposition process and the second deposition process are performed using ion beam deposition. In some embodiments, the first deposition process is performed using ion beam deposition, and the second deposition process is performed using sputter deposition. In some embodiments, the absorber layer is etched using an electron beam by using NOCl2 as precursor gas. In some embodiments, etching the absorber layer comprises performing a chloride-based or fluoride-based dry etching on the absorber layer, and applying sulfuric peroxide mixture (SPM) cleaning solution on the absorber layer after performing the chloride-based or fluoride-based dry etching. In some embodiments, the capping layer is substantially unchanged in thickness before and after the anneal process. In some embodiments, the first deposition process is performed such that a topmost layer of the reflective multilayer stack includes molybdenum.

In some embodiments, an extreme ultraviolet lithography (EUVL) method includes turning on a droplet generator to eject a metal droplet toward a zone of excitation in front of a collector, turning on a laser source to emit a laser toward the zone of excitation, such that the metal droplet is heated by the laser to generate EUV radiation, guiding the EUV radiation, by using one or more first optics, toward a reflective mask in an exposure device, the reflective mask comprising a Si/Mo multilayer stack and a ruthenium layer, and a diffusion barrier layer interposing the Si/Mo multilayer stack and the ruthenium layer, and guiding the EUV radiation, by using one or more second optics, reflected from the reflective mask toward a photoresist coated substrate in the exposure device. In some embodiments, the diffusion barrier layer has a thickness in a range from 1 nm to 3 nm. In some embodiments, the diffusion barrier layer is ruthenium-free.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An extreme ultraviolet (EUV) mask, comprising:
a substrate;
a reflective multilayer stack on the substrate, wherein the reflective multilayer stack comprises alternately stacked first layers and second layers;
a diffusion barrier layer on the reflective multilayer stack, wherein the diffusion barrier layer has a composition different from compositions of the first layers and the second layers;
a capping layer on the diffusion barrier layer; and
a patterned absorber layer on the reflective multilayer stack.

2. The EUV mask of claim 1, wherein the diffusion barrier layer has a lower reactivity with the capping layer than the reflective multilayer stack.

3. The EUV mask of claim 1, wherein the diffusion barrier layer is free from Ru.

4. The EUV mask of claim 1, wherein the diffusion barrier layer is free from molybdenum.

5. The EUV mask of claim 1, wherein the diffusion barrier layer comprises B₄C, BN, BCN, SiN₂, Si₃N₄, SiB₆, SiC, ZrC, ZrN, C, Co, Ir, Zr, RhZr, RuN, HfZr, HfN, NbZr, Nb₄C₃, NbC, NbN, NbSi, or a combination thereof.

6. The EUV mask of claim 1, wherein diffusion barrier layer has a thickness in a range from 1 nm to 3 nm.

7. The EUV mask of claim 1, wherein the reflective multilayer stack includes a topmost layer made of molybdenum, and the diffusion barrier layer is in contact with the topmost layer.

8. The EUV mask of claim 1, wherein the reflective multilayer stack includes a topmost layer made of silicon, and the diffusion barrier layer is in contact with the topmost layer.

9. A method of forming an EUV mask, comprising:
performing a first deposition process to form a reflective multilayer stack over a substrate, the reflective multilayer stack comprising alternating stacked molybdenum layer and silicon layers;
performing a second deposition process to form a diffusion barrier layer on the reflective multilayer stack;
forming a capping layer on the diffusion barrier layer, wherein the diffusion barrier has a lower reactivity with the capping layer than the reflective multilayer stack;
performing an anneal process after forming the capping layer;
forming an absorber layer on the capping layer; and
etching the absorber layer to form a pattern in the absorber layer.

10. The method of claim 9, wherein the diffusion barrier layer does not react with the capping layer during the anneal process.

11. The method of claim 9, wherein the first deposition process and the second deposition process are performed in a same chamber.

12. The method of claim 9, wherein the first deposition process and the second deposition process are performed using ion beam deposition.

13. The method of claim 9, wherein the first deposition process is performed using ion beam deposition, and the second deposition process is performed using sputter deposition.

14. The method of claim 9, wherein the absorber layer is etched using an electron beam by using NOCl₂ as precursor gas.

15. The method of claim 9, wherein etching the absorber layer comprises:
performing a chloride-based or fluoride-based dry etching on the absorber layer; and
applying sulfuric peroxide mixture (SPM) cleaning solution on the absorber layer after performing the chloride-based or fluoride-based dry etching.

16. The method of claim 9, wherein the capping layer is substantially unchanged in thickness before and after the anneal process.

17. The method of claim 9, wherein the first deposition process is performed such that a topmost layer of the reflective multilayer stack includes molybdenum.

18. An extreme ultraviolet lithography (EUVL) method, comprising:
turning on a droplet generator to eject a metal droplet toward a zone of excitation in front of a collector;
turning on a laser source to emit a laser toward the zone of excitation, such that the metal droplet is heated by the laser to generate EUV radiation;
guiding the EUV radiation, by using one or more first optics, toward a reflective mask in an exposure device, the reflective mask comprising a Si/Mo multilayer stack and a ruthenium layer, and a diffusion barrier layer interposing the Si/Mo multilayer stack and the ruthenium layer; and
guiding the EUV radiation, by using one or more second optics, reflected from the reflective mask toward a photoresist coated substrate in the exposure device.

19. The method of claim 18, wherein the diffusion barrier layer has a thickness in a range from 1 nm to 3 nm.

20. The method of claim 18, wherein the diffusion barrier layer is ruthenium-free.
